(19) United States
(12) Patent Application Publication
(10) Pub. No.: US 2025/0306575 A1
(43) Pub. Date: Oct. 2, 2025

(54) USER-INTERACTABLE DESIGN FOR MANUFACTURABILITY OF METAL TUBING

(71) Applicant: OSH CUT, INC., SPANISH FORK, UT (US)

(72) Inventors: Caleb Hunter Chamberlain, Payson, UT (US); Eric Russell Mansfield, Spanish Fork, UT (US)

(21) Appl. No.: 19/090,871

(22) Filed: Mar. 26, 2025

Related U.S. Application Data
(60) Provisional application No. 63/570,423, filed on Mar. 27, 2024.

(51) Int. Cl. G05B 19/418

(52) U.S. Cl. CPC G05B 19/41865; G05B 2219/32128

(57) ABSTRACT

A system for facilitating user-interactable design for manufacturability of metal tubing is configurable to (i) receive an input file comprising a representation of a metal tubing part; (ii) determine manufacturability of the metal tubing part by applying one or more manufacturing rules to the metal tubing part or the modified metal tubing part; (iii) in response to determining that the metal tubing part is not manufacturable in accordance with the one or more manufacturing rules, generate a modified metal tubing part based on the metal tubing part, wherein the modified metal tubing part satisfies the one or more manufacturing rules; (iv) present the modified metal tubing part and the metal tubing part within a user interface, wherein the modified metal tubing part and the metal tubing part are presented simultaneously or alternately; and (v) selectively enable order placement functionality within the user interface.

### CROSS-REFERENCE TO RELATED APPLICATIONS

This application claims priority to and the benefit of U.S. Provisional Patent Application No. 63/570,423, filed on Mar. 27, 2024, and entitled “USER-INTERACTABLE DESIGN FOR MANUFACTURABILITY OF METAL TUBING”, the entirety of which is incorporated herein by reference for all purposes.

### BACKGROUND

The manufacturing of sheet metal parts often includes sheet metal bending, which involves the deformation of metal sheets along a straight axis to achieve a desired angle or shape. Sheet metal bending is performed to create components that are integral to a wide variety of industries, including automotive, aerospace, electronics, construction, and others. Bending operations are executed using specialized machinery, such as press brakes, which apply force to the metal sheet at a specific location, causing it to bend. The complexity of the bend can range from simple, single-angle bends to complex sequences requiring precise control over angle, direction, and sequence.

Metal tubing parts are also used in various industries, such as automotive, construction, aerospace, medical devices, and others. The manufacturing of metal tubing parts often includes metal tube cutting, which involves precise cutting of metal tubes into specified lengths or shapes, catering to the diverse requirements of different applications. The techniques used for cutting metal tubes can vary significantly, depending on factors like the type of metal, the thickness of the tube, and the desired finish of the cut edge. Traditional methods include saw cutting, which is versatile but can be slower and less precise for complex or high-volume tasks. More advanced methods, such as laser cutting and waterjet cutting, offer higher precision, faster processing times, and the ability to cut intricate shapes or patterns without physical contact with the tube.

The subject matter claimed herein is not limited to embodiments that solve any challenges or that operate only in environments such as those described above. Rather, this background is only provided to illustrate one exemplary technology area where some embodiments described herein may be practiced.

### BRIEF DESCRIPTION OF THE DRAWINGS

In order to describe the manner in which the above-recited and other advantages and features can be obtained, a more particular description of the subject matter briefly described above will be rendered by reference to specific embodiments which are illustrated in the appended drawings. Understanding that these drawings depict only typical embodiments and are not therefore to be considered to be limiting in scope, embodiments will be described and explained with additional specificity and detail through the use of the accompanying drawings in which:

FIG. 1 illustrates an example user interface display for obtaining an input file representing a custom metal part, in accordance with implementations of the disclosed subject matter.

FIG. 2 illustrates an example user interface display that conceptually depicts the determination of manufacturability of a custom sheet metal part obtained according to FIG. 1, in accordance with implementations of the disclosed subject matter.

FIG. 3 illustrates an example user interface display that includes an indication of manufacturability of the custom sheet metal part, in accordance with implementations of the disclosed subject matter.

FIGS. 4, 5, and 6 illustrate example user interface displays that include a flat pattern of the custom sheet metal part and that also provide an indication of manufacturability of the custom sheet metal part, in accordance with implementations of the disclosed subject matter.

FIGS. 7 and 8 illustrate example user interface displays that include a manufacturing simulation of the custom sheet metal part and that also provide an indication of manufacturability of the custom sheet metal part, in accordance with implementations of the disclosed subject matter.

FIG. 9 illustrates an example user interface display for obtaining a material selection for manufacture of the custom sheet metal part, in accordance with implementations of the disclosed subject matter.

FIG. 10 illustrates an example user interface display that includes a flat pattern of the custom sheet metal part and that also provide an indication of manufacturability of the custom sheet metal part, in accordance with implementations of the disclosed subject matter.

FIGS. 11 and 12 illustrate example user interface displays that include a flat pattern of the custom sheet metal part and that include sheet metal part characteristics, in accordance with implementations of the disclosed subject matter.

FIG. 13 illustrates an example user interface display that includes a modified custom sheet metal part based on user modifications to the sheet metal part characteristics, in accordance with implementations of the disclosed subject matter.

FIG. 14 illustrates an example user interface display that includes the custom sheet metal part without modifications, in accordance with implementations of the disclosed subject matter.

FIGS. 15, 16, and 17 illustrate example user interface displays that include a manufacturing simulation of the modified custom sheet metal part, in accordance with implementations of the disclosed subject matter.

FIG. 18 illustrates an example user interface display that includes order placement functionality, in accordance with implementations of the disclosed subject matter.

FIG. 19 illustrates an example user interface display that includes a bend sequence configuration for manufacturing a custom sheet metal part, in accordance with implementations of the disclosed subject matter.

FIGS. 20 and 21 illustrate example user interface displays that include a back gauge configuration for manufacturing a custom sheet metal part, in accordance with implementations of the disclosed subject matter.

FIG. 22 illustrates an example user interface display that includes a manufacturing simulation of a custom sheet metal part, in accordance with implementations of the disclosed subject matter.

FIG. 23 illustrates an example user interface display that includes an indication of manufacturability of a custom metal tubing part, in accordance with implementations of the disclosed subject matter.

FIGS. 24, 25, 26, and 27 illustrate example user interface displays showing various aspects of obtaining a material selection for manufacture of a custom metal tubing part, in accordance with implementations of the disclosed subject matter.

FIGS. 28, 29, 30, 31, 32, 33, 34, 35, and 36 illustrate example user interface displays that show various aspects associated with presenting metal tubing parts and modified metal tubing parts, in accordance with implementations of the disclosed subject matter.

FIGS. 37 and 38 illustrate example user interface displays showing aspects of selecting a sheet metal or metal tubing framework for processing of a metal tubing part represented in an input file, in accordance with implementations of the disclosed subject matter.

FIG. 39 depicts example components of a system that may comprise or be configurable to perform various embodiments.

### DETAILED DESCRIPTION

Disclosed embodiments are directed to systems and methods for facilitating user-interactable design for manufacturability of sheet metal and metal tubing.

As noted above, sheet metal bending is performed to manufacture sheet metal parts in numerous industries. Many custom metal fabrication shops offer sheet metal manufacturing services that include sheet metal bending. However, normal workflows adopted by many custom metal fabrication shops are associated with numerous challenges. For instance, to receive custom sheet metal bending services, a customer typically provides a model or schematic of the sheet metal part to be manufactured to a custom fabrication shop. The custom fabrication shop then performs a manufacturability analysis to determine whether the custom fabrication shop has the capability to manufacture the desired sheet metal part (e.g., to determine whether the proper material, machinery, tooling, etc. are available). For example, a laser cutting programmer of a custom fabrication shop may be tasked with determining whether appropriate blanks can be cut to manufacture a desired part, and, subsequently, a press brake programmer may be tasked with determining whether available press brake machinery and tooling can make the bends necessary to produce the desired part, etc. If the part is not manufacturable, the custom fabrication shop can communicate such issues to the customer, which can prompt the customer to redesign the desired part to conform to the manufacturing capabilities of the custom fabrication shop.

Custom fabrication shops engage in similar manufacturability analyses with respect to the manufacture of metal tubing parts. For instance, to determine manufacturability of a metal tubing part, a custom fabrication shop may assess whether appropriate tubing materials are available to satisfy the part requirements and determine whether the technical capabilities of their laser cutting machine(s) (and/or other machines) can handle the part specifications (e.g., cut depth, design intricacies, edge quality, tolerances, etc.). Similar to sheet metal manufacturability analyses, if the metal tubing part is not manufacturable, the custom fabrication shop can communicate such issues to the customer, which can prompt the customer to redesign the desired metal tubing part to conform to the manufacturing capabilities of the custom fabrication shop.

Conventional manufacturability analyses, as described above, are often time-intensive, labor-intensive, and costly (e.g., due to the specialized labor required for such analyses) for both custom fabrication shops and their customers. Custom fabrication shops can thus be very selective about which customers to engage with on such manufacturability analyses, which can limit the ability of new customers to secure custom metal part manufacturing services.

At least some disclosed embodiments are directed to systems, methods, and techniques for facilitating user-interactable design for manufacturability of sheet metal parts and/or metal tubing parts. At least some disclosed embodiments can provide a user-interactable interface (e.g., a web-accessible interface or device application interface) that allows customers to submit a custom part (e.g., via upload) to trigger automatic, server-based design for manufacturability (DFM) processes to be performed on the custom part. For sheet metal parts, the DFM processes can include flattening the custom part and performing virtual bending operations on the flattened part. The virtual bending operations can be performed in accordance with manufacturing configurations available to a specific custom fabrication shop/facility (e.g., press brake machinery availability and capability, press brake tooling available, sheet metal material availability and dimensions, etc.). For metal tubing parts, the DFM processes can include ensuring that tubing length, bevel characteristics, tooling access, cut clearance, cut depth, and/or other requirements for the custom part are satisfiable by tube cutting machinery available to the specific custom fabrication shop/facility.

Based on the automated DFM processes, a manufacturability indicator can be presented on the user interface, which can indicate whether the custom part is manufacturable by the specific custom fabrication shop (or set of shops/facilities). The user interface can present part characteristics that are user-modifiable, which can enable users to adjust design aspects of the custom part to achieve or approach manufacturability. For sheet metal parts, the part characteristics can include bend radius, bend angle, bend direction, and/or other characteristics. For metal tubing parts, the part characteristics can include tubing material, bevel angle, bevel consistency, metal tube length, cut depth, cut positioning, and/or other characteristics. In some implementations, the user interface can be configured to provide a manufacturing simulation that simulates manufacturing of the custom part (e.g., visually simulating bending operations, tube cutting operations, etc.), and the simulation can emphasize aspects of the custom part (or manufacturing process therefor) that cause failure of the manufacturability test/analysis (e.g., collisions with tooling, insufficient cut clearance, etc.).

Based on user modifications to the part characteristics, a modified part may be generated (e.g., using server resources), and automated DFM processes may be performed (e.g., using server resources) to determine whether the modified part is manufacturable. The manufacturability indicator may be updated based on the updated DFM processes performed for the modified part, which can beneficially allow users to make iterative modifications to their part to achieve or approach manufacturability (without costly back-and-forth between personnel of the custom fabrication shop and the customer). In some instances, the user interface can simultaneously display or selectively toggle between displaying the original custom part (e.g., as originally provided by the customer and on which initial DFM processing was performed) and the modified part to allow users to visually inspect differences in characteristics (e.g., differences in material thickness, bend radius, bevel angle, etc.).

In some instances, the user interface can present manufacturing configurations that are available to the specific custom fabrication shop, which can also enable users to adjust manufacturing configurations to achieve or approach manufacturability for their custom part. For sheet metal parts, example manufacturing configurations can include punch configurations, die configurations, back gauge configurations, bend sequence configurations, machine selection configurations, part orientation (during bending), etc.

When the custom part (or modified part generated based on user modifications) is determined to be manufacturable (based on automated DFM processes), the user interface can be configured to selectively enable price calculation/updating and/or order placement functionality, which can allow users to place an order that triggers manufacturing of the custom part (or modified part) by the specific custom fabrication shop (or manufacturing facility). Such functionality can significantly reduce the burden associated with acquiring (and providing) price quotes for custom metal fabrication, which can improve accessibility and experiences.

Having just described some of the various high-level features and benefits associated with the disclosed subject matter, attention will now be directed to the Figures, which illustrate various conceptual representations, architectures, methods, and/or supporting illustrations related to the disclosed embodiments.

Various Figures described hereinbelow show example user interface displays, which can be displayed on one or more devices/systems pursuant to execution of program instructions associated with an application (whether locally stored or accessed via a web browser or other mechanism). As used herein, a “user interface” can refer to a point of interaction between a user and a digital device that displays content (e.g., “user interface content” or “user interface display”) associated with such an application and/or can receive user input for interacting with the displayed content (e.g., a display screen with a controller such as a mouse and/or keyboard, a desktop or laptop computer, a touch screen, a wearable device, etc.). The content associated with the application that is displayed on the user interface can comprise one or more pages or workflow steps/presentations, amongst which the user can navigate via control input provided via the user interface within an interactive session.

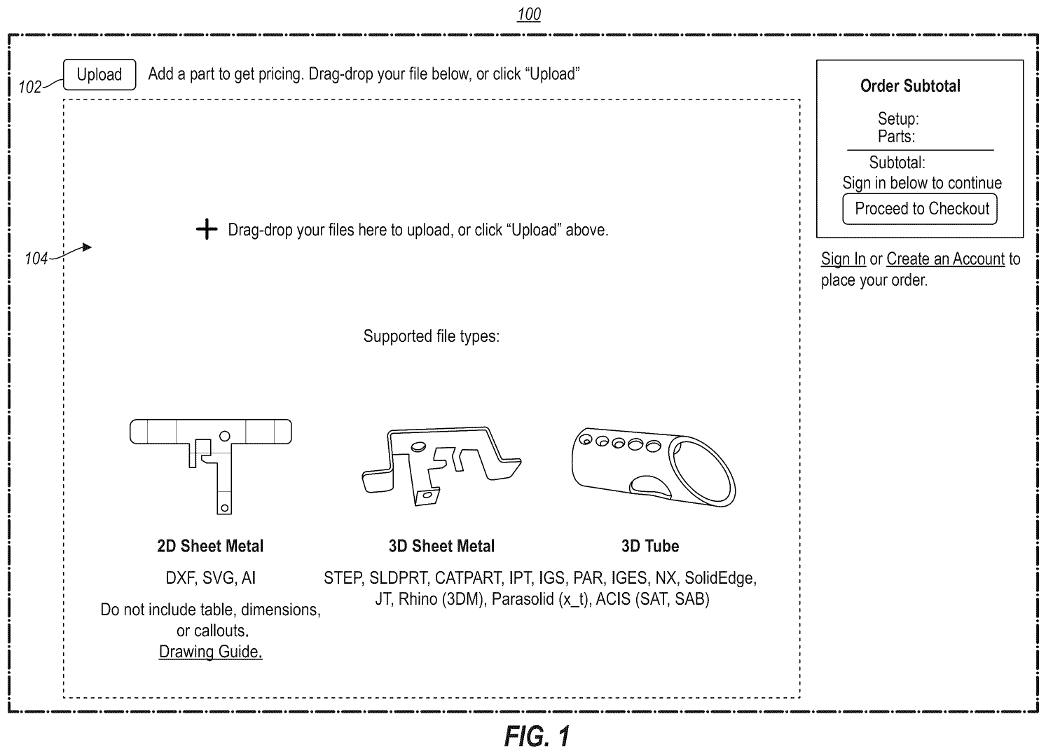

FIG. 1 illustrates an example user interface display 100 for obtaining an input file representing a custom metal part. For instance, the user interface display 100 includes an upload element 102, which may be selectable by users to enable submission of an input file. The user interface display 100 of FIG. 1 also includes a drag-drop space 104 whereon users may drag and drop an input file for submission. The input file to be submitted can be locally stored on a user device displaying the user interface display 100. The input file can take on various forms, such as a 2D drawing file (e.g., DFX, SVG, AI, and/or others) or a 3D model file (e.g., STEP, SLDPRT, CATPART, IPT, IGS, PAR, IGES, NX, SolidEdge, JT, 3DM, x_t, SAT, SAB, and/or others). The input file submitted by the user (e.g., interacting with the user interface display 100) can include a representation of a sheet metal part (e.g., a custom sheet metal part).

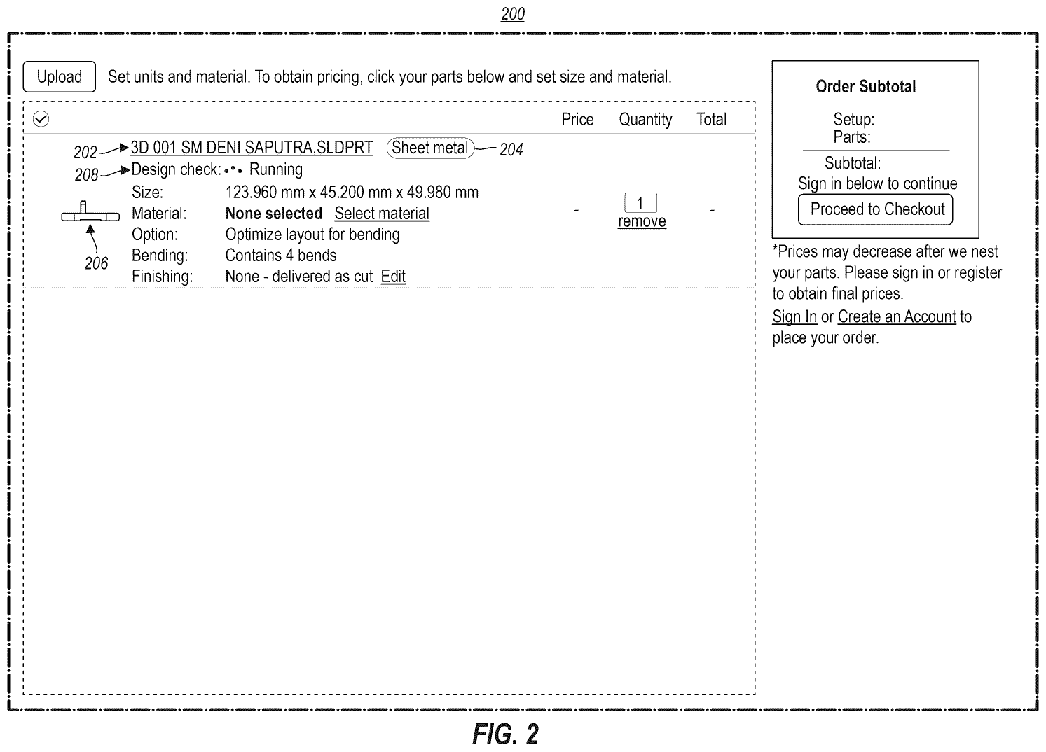

FIG. 2 illustrates an example user interface display 200 that conceptually depicts the determination of manufacturability of the sheet metal part represented by the input file discussed above with reference to FIG. 1. FIG. 2 conceptually depicts the input file 202 (by reference to its name) as well as a type label 204 that states “sheet metal”. The input file 202 can be preprocessed (e.g., using server and/or local resources) to determine whether the input file 202 includes a representation of a sheet metal part (or another type of part, such as a metal tubing part as will be described hereinafter). The type label 204 can be defined and/or presented based on the outcome of such preprocessing.

FIG. 2 also conceptually depicts the sheet metal part 206 represented by the input file 202 (by showing a thumbnail depiction thereof). FIG. 2 also conceptually depicts the performance of the determination of manufacturability (e.g., “DFM processing”) by displaying a design check element 208, which includes a “Running” label indicating that the DFM processing for the sheet metal part 206 is underway/ongoing. In some implementations, such as where the input file 202 comprises a 3D model file, the DFM processing for a sheet metal part (e.g., sheet metal part 206) includes generating a flat pattern based on sheet metal part 206 represented by the input file 202. The flat pattern can be generated by applying virtual inverse bending operations to the sheet metal part 206. Where the input file 202 comprises a 2D drawing file, the flat pattern can be generated directly from the input file 202 (one or more preprocessing operations may be applied).

After acquisition of a flat pattern for the sheet metal part 206 represented by the input file 202, the DFM processing can include applying one or more virtual bending operations to the flat pattern. The virtual bending operation(s) can be based on manufacturing configurations available to one or more specific manufacturing facilities (or one or more “designated” manufacturing facilities) that can receive an order for custom sheet metal part fabrication arising from the user's interaction with the user interface (e.g., based on the user's interaction with a web application that underlies the various example user interface displays shown/described herein). In this regard, the manufacturing configurations used for the virtual bending operation(s) can be based on inventory-specific and/or machine-specific data associated with the designated manufacturing facility or facilities, which can be dynamically updated to reflect current conditions (e.g., to reflect changes in material, tooling, or machine availability, etc.). Example manufacturing conditions specific to one or more manufacturing facilities that can predicate virtual bending operations for DFM processing can include available machinery (e.g., available press brake machine types), available die configurations (e.g., die type, die size, etc.), available punch configurations (e.g., punch type, punch size, etc.), available back gauge configurations (e.g., positions assumable by one or more back gauges of one or more press brake machines), and/or others. In some instances, the DFM processing for determining whether a sheet metal part (e.g., sheet metal part 206) is manufacturable can depend on part-specific manufacturing configurations, such as potential bend sequences for manufacturing the sheet metal part (e.g., even considering ordering of partial bends), potential part orientations for performing the bends to manufacture the sheet metal part, etc.

In some implementations, the DFM processing to determine whether the sheet metal part 206 is manufacturable is performed using one or more server resources. The DFM processing can involve iteratively applying different sets of virtual bending operations to the flat pattern for the sheet metal part 206 that each use different manufacturing configurations (e.g., capturing variations in machinery used, tooling used, back gauge configurations used, bend sequences used, part orientations used, etc.), which can allow a system to determine one or more manufacturing configurations for manufacturing the sheet metal part 206 that avoid, reduce, or minimize potential errors (e.g., collisions, lack of flange support, etc.).

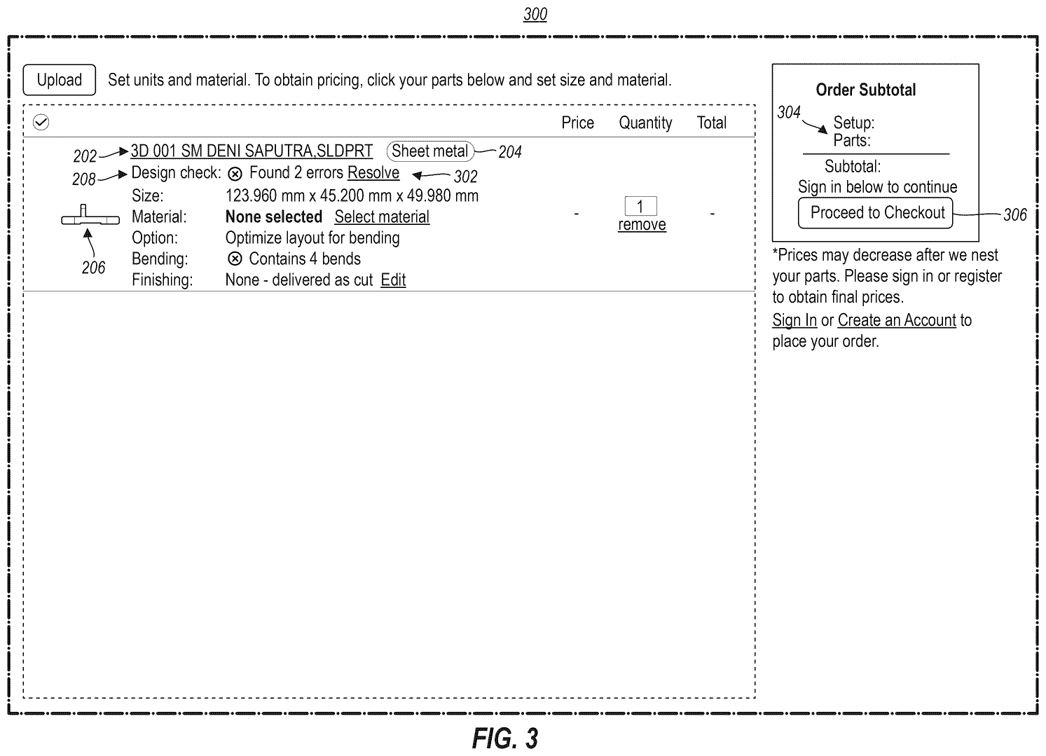

FIG. 3 illustrates an example user interface display 300 that includes a manufacturability indicator 302 (or an “indication of manufacturability”) for the sheet metal part 206 represented by the input file 202 that was subjected to DFM processing as described above. In the example of FIG. 3, the manufacturability indicator 302 indicates (for illustrative purposes) that one or more manufacturing errors exist (by stating “Found 2 errors”), which can indicate that the sheet metal part 206 in its current form is not manufacturable by the one or more designated manufacturing facilities whose available manufacturing configurations were used to perform the DFM processing. As will be described in more detail hereinafter, a manufacturability indicator can take on various forms, provide various types of information (e.g., problem regions, warnings, recommended modifications), and/or be presented in conjunction with various other user interface display elements.

FIG. 3 furthermore illustrates a price region 304 and a checkout element 306. While the manufacturability indicator 302 indicates that the sheet metal part 206 is not manufacturable, the system(s) providing the user interface display 300 (e.g., a server and/or a user device executing a web-based application) can refrain from populating the price region 304 with price information and/or can refrain from enabling checkout or order placement functionality via the checkout element 306. In some implementations, the system(s) providing the user interface display 300 can selectively generate or update price information and/or selectively enable order placement functionality when it is determined that a subject sheet metal part is manufacturable by a designated manufacturing facility.

The user interface display 300 of FIG. 3 illustrates the depiction of the input file 202 as a selectable element, which can be selected to trigger presentation of additional user interface displays for assessing or modifying various characteristics of the sheet metal part 206 (and/or flat patterns or modified sheet metal parts generated based on the sheet metal part 206).

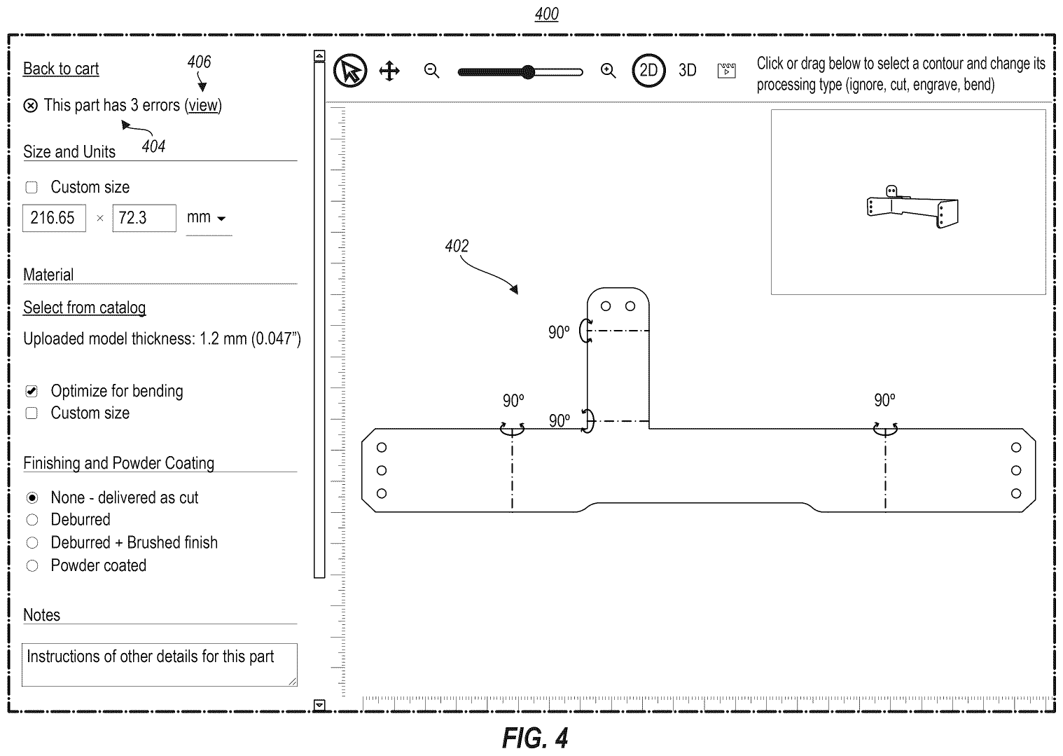

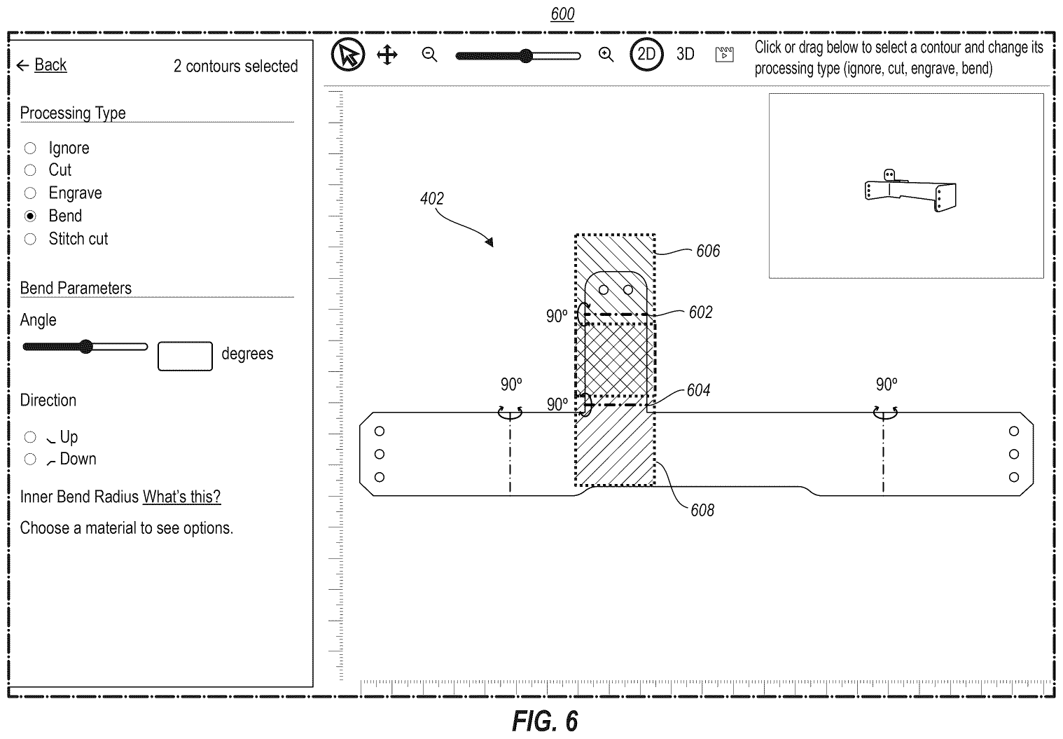

FIGS. 4, 5, and 6 illustrate example user interface displays 400, 500, and 600, respectively, that include a flat pattern 402 of the sheet metal part 206. Each of the user interface displays 400, 500, and 600 also includes a respective indication of manufacturability for the sheet metal part 206. For instance, user interface display 400 includes a manufacturability indicator 404 that indicates (for illustrative purposes) that various errors exist with respect to manufacturing of the sheet metal part 206 (and therefore that the sheet metal part 206 is not manufacturable by the designated manufacturing facility/facilities). The manufacturability indicator 404 includes a selectable element 406 that can allow users to drill down on specific aspects of the errors detected during the DFM process.

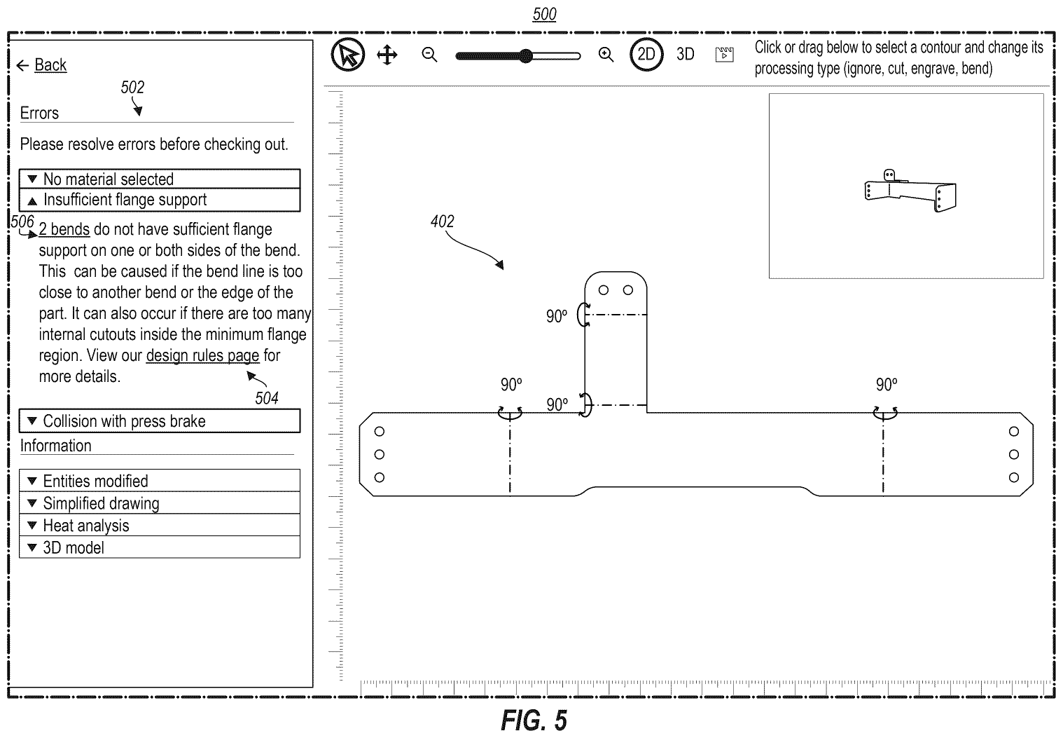

User interface display 500 can be displayed after selection of the selectable element 406 of user interface display 400. In the example shown in FIG. 5, the user interface display 500 includes a manufacturability indicator 502 that provides more granular detail related to the errors detected based on the DFM process. For instance, the manufacturability indicator 502 of the user interface display 500 indicates (for illustrative purposes) that no material has been selected, insufficient flange support has been detected for one or more bends, and collision with the press brake has been detected for one or more bends. The manufacturability indicator 502 illustrates the different manufacturing errors as collapsible banners that provide additional details when opened. In the user interface display 500, the banner related to insufficient flange support is opened, providing the user with a description 504 of the insufficient flange support error detected during DFM processing. For instance, the description 504 includes a selectable element 506 indicating the quantity of bends for which insufficient flange support was detected. Selection of the selectable element 506 can trigger display of the particular bends for which insufficient flange support was detected on the flat pattern 402. User interface display 600 displays the bends 602 and 604 on the flat pattern 402 for which insufficient flange support was detected. Additionally, the user interface display 600 depicts die contact areas 606 and 608 (for bends 602 and 604, respectively) on the user interface display 400, which can visually indicate to users aspects of the bends 602 and 604 that lack flange support. In this regard, a manufacturability indicator can indicate problem regions associated with the sheet metal part 206 (e.g., by showing and/or linking to bends or other regions of the part determined to cause manufacturing failures/issues via the DFM processing).

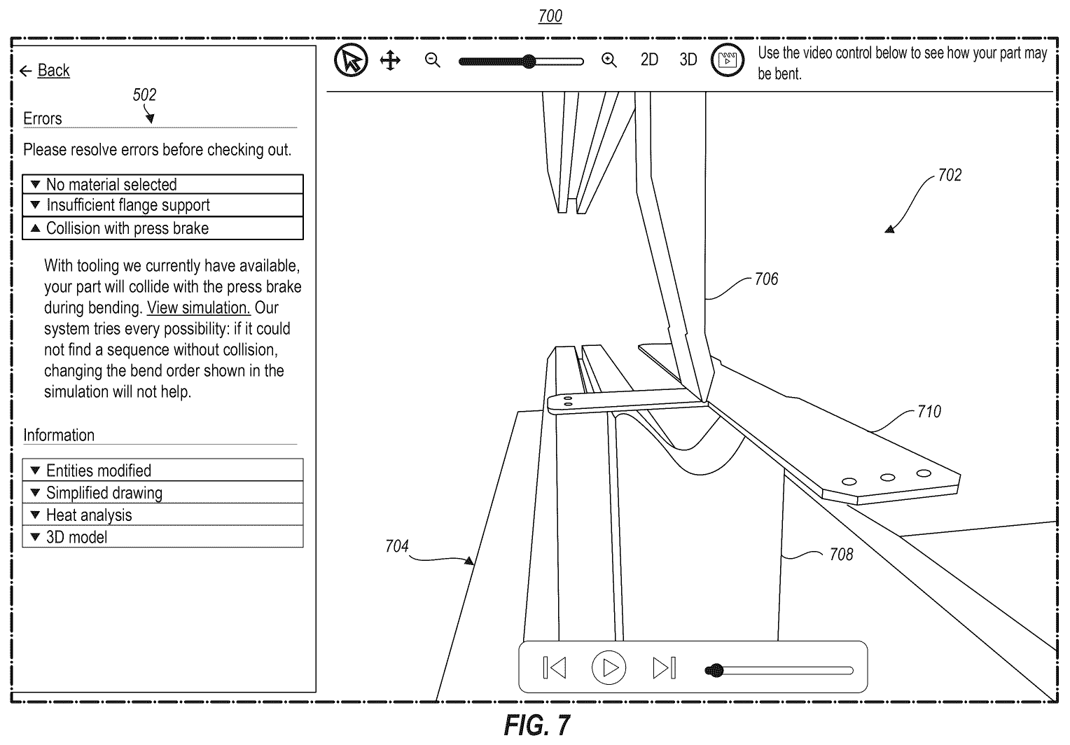

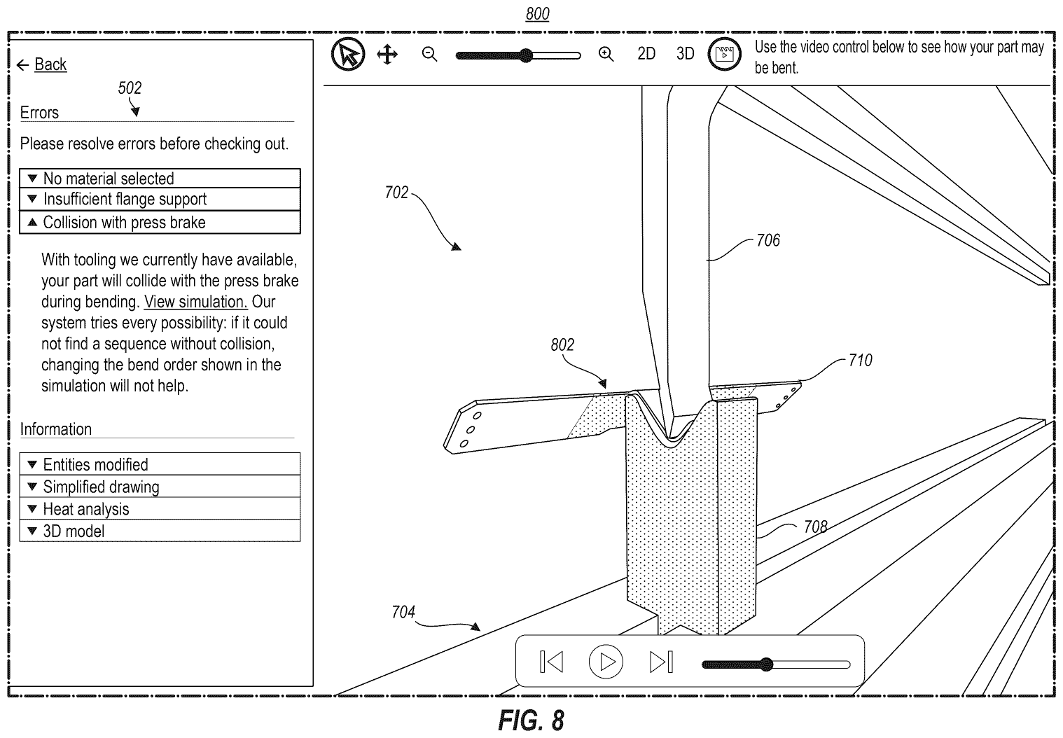

FIGS. 7 and 8 illustrate example user interface displays 700 and 800, respectively, that include a manufacturing simulation 702 for the sheet metal part 206. In the examples of FIGS. 7 and 8, the manufacturing simulation 702 can depict a press brake machine 704 with a punch 706 and a die 708 connected thereto to facilitate bending of a blank 710 that corresponds to the flat pattern 402. In the manufacturing simulation 702, the press brake machine 704 can step through multiple bending steps, visually illustrating movement of the press brake machine 704 to press the blank 710 into contact with the die 708 to facilitate bending of the blank 710 to form a sheet metal part (e.g., corresponding to sheet metal part 206). The specific press brake machine 704, punch 706, die 708, orientation of the blank 710 for bends, bend sequence for bending the blank 710, bend direction for bending the blank 710, etc. used in the various bending operations shown in the manufacturing simulation 702 can be selected based on the DFM processes performed for the sheet metal part 206 as described above. For instance, the manufacturing simulation 702 can visually depict the manufacturing configuration(s) determined to avoid or minimize manufacturing errors after iteratively testing multiple different manufacturing configurations as described above. In some instances, different steps or bend operations of the manufacturing simulation 702 can use different manufacturing configurations (e.g., different machines, punches, dies, etc.).

In the example shown in FIG. 7, the user interface display 700 includes the same manufacturability indicator 502 as the user interface display 500 described above with reference to FIG. 5. In the user interface display 700, the error banner of the manufacturability indicator 502 describing collision with the press brake is expanded, providing users with additional information related to this error. FIG. 8 shows the manufacturing simulation 702 showing a subsequent bending operation relative to that shown in FIG. 7. In the user interface display 800, the die 708 and a region 802 of the blank 710 are highlighted or otherwise emphasized to visually depict the collision with the press brake described in the manufacturability indicator 502. Such functionality (i.e., visually depicting collisions or other failures in a manufacturing simulation 702 for manufacturing a sheet metal part 206) can readily communicate to users the problem regions associated with a sheet metal part 206, which can guide user efforts in modifying aspects of the sheet metal part 206.

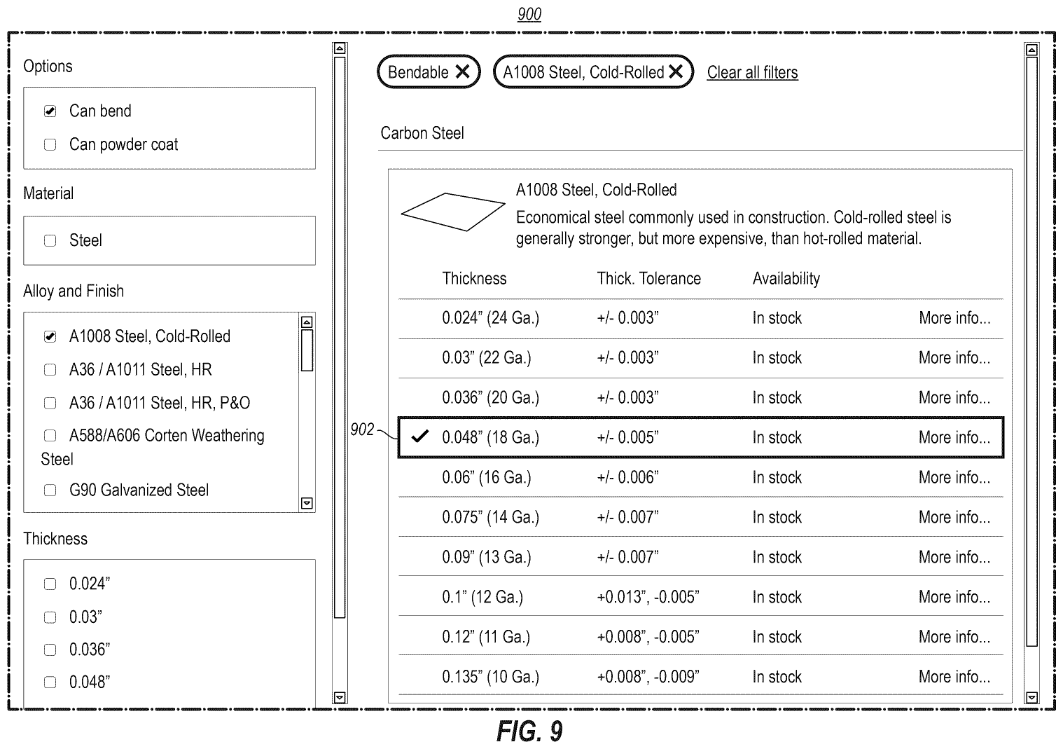

FIG. 9 illustrates an example user interface display 900 for obtaining a material selection for manufacture of the sheet metal part 206. The user interface display 900 can provide various filtering operations, such as whether the material is bendable, thickness, alloy and finish, etc. In the example shown in FIG. 9, a user has provided input designating a selected material 902 (i.e., 18 Ga. A1008 steel, cold-rolled). In some instances, based on the selected material 902, a modified sheet metal part is generated using attributes of the selected material and attributes of the sheet metal part 206 represented by the input file 202. For instance, using the thickness of the selected material 902, a system may generate a modified sheet metal part by adapting bend radii and/or bend locations of the flat pattern 402 based on the sheet metal part 206 represented by the input file 202 in a manner that preserves the overall size of the sheet metal part 206.

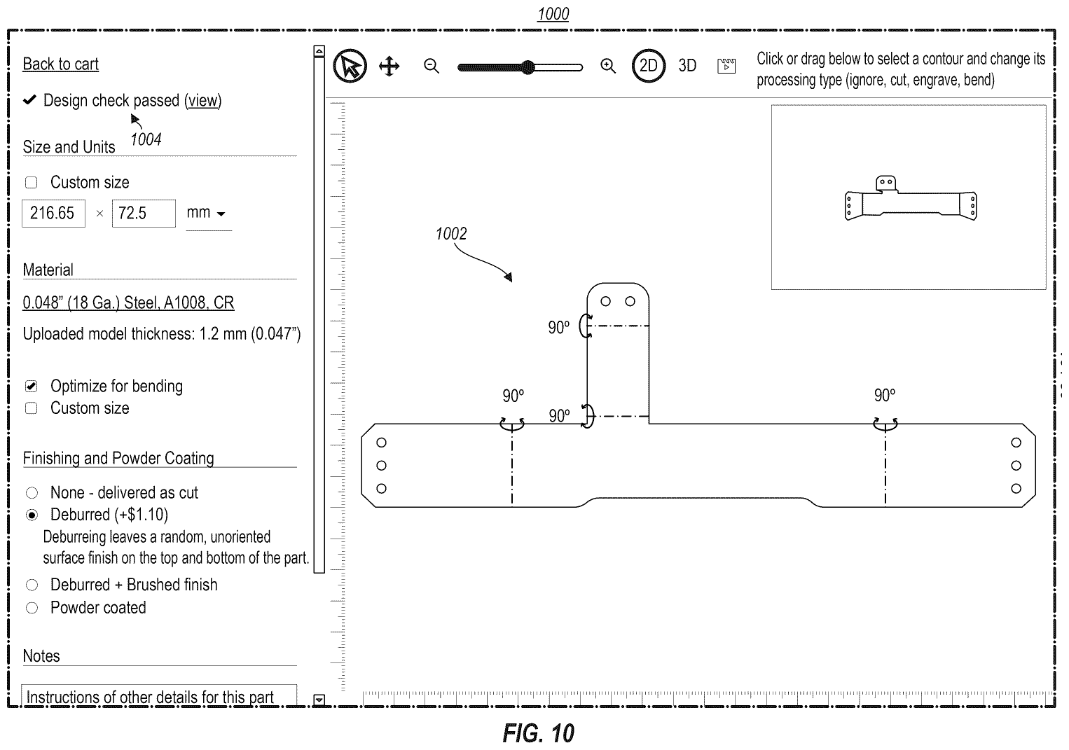

In some implementations, after generating a modified sheet metal part based on a selected material 902 and the sheet metal part 206 as represented in the input file 202, the system may perform DFM processes to determine manufacturability of the modified sheet metal part. FIG. 10 illustrates an example user interface display 1000 that includes a modified flat pattern 1002 for forming a modified sheet metal part (e.g., which may be generated based on the selected material 902 and the sheet metal part 206 as represented by the input file 202, as noted above). DFM processing may be performed using the modified flat pattern 1002, such as by applying virtual bending operations thereto using manufacturing configurations available to one or more designated manufacturing facilities to attempt to form the modified sheet metal part. The user interface display 1000 includes a manufacturability indicator 1004. In the example shown in FIG. 10, based on the DFM processing performed for the modified sheet metal part, the manufacturability indicator 1004 indicates (for illustrative purposes) that the design check is passed (i.e., that the modified sheet metal part is manufacturable by the one or more designated manufacturing facilities).

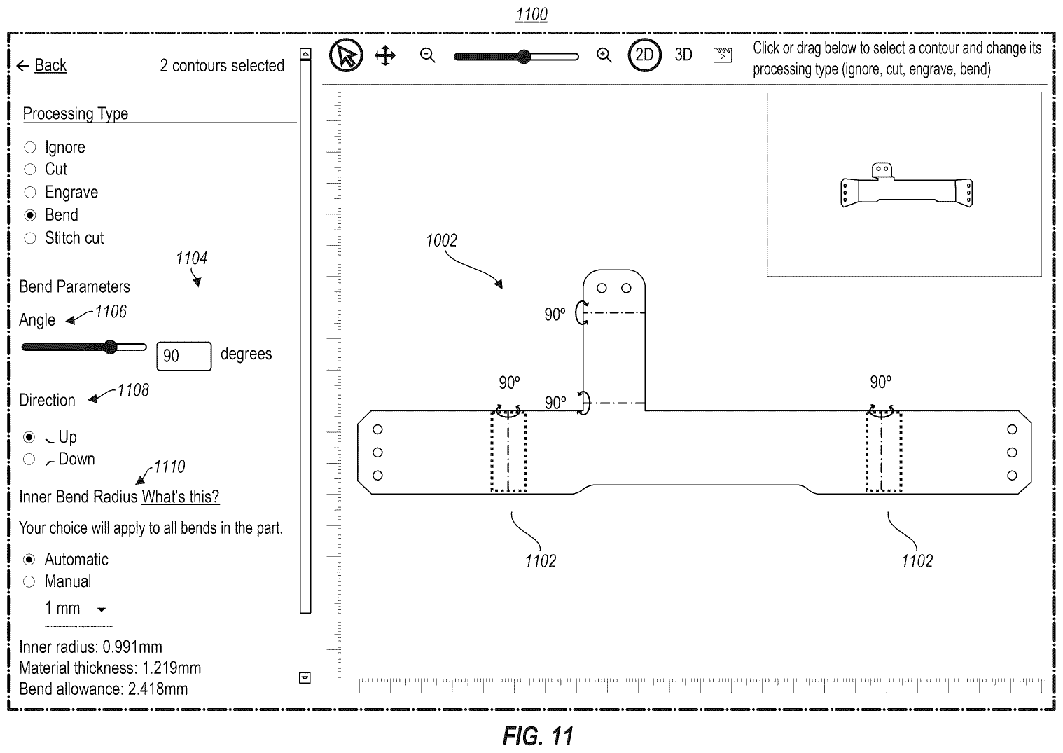

FIG. 11 illustrates an example user interface display 1100 that shows the modified flat pattern 1002 described above. In the example shown in FIG. 11, bends 1102 of the modified flat pattern 1002 highlighted or otherwise emphasized to illustrate selection of the bends 1102 (e.g., after detecting user input directed to the bends 1102). As illustrated in FIG. 11, the user interface display 1100 can display characteristics 1104 of the bends 1102 of the modified flat pattern 1002. The characteristics 1104 can include, for example, bend angle 1106, bend direction 1108, bend radius 1110, and/or others. At least some of the characteristics 1104 can be presented in a manner that allows user modification thereto. For instance, the bend angle 1106 is shown with a slide bar and an entry field, permitting user modification to the bend angle 1106 for the bends 1102. As another example, the bend direction 1108 is presented with selectable options (i.e., “Up” or “Down”). As yet another example, the bend radius 1110 is presented with selectable options for selecting “Automatic” determination of the bend radius for the bends 1102 (e.g., based on the selected material 902 and/or the appropriate machine and/or tooling determined via DFM processing) or “Manual” selection of the bend radius 1110 for the bends 1102.

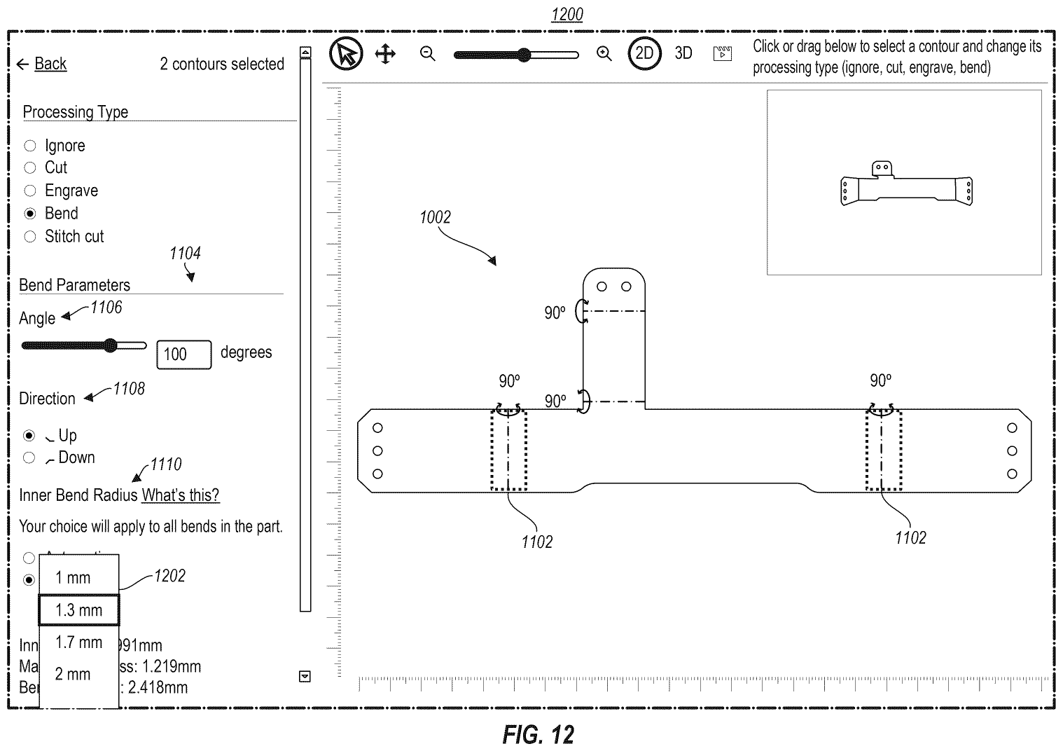

FIG. 12 illustrates an example user interface display 1200 in which characteristics 1104 of the bends 1102 of the modified flat pattern 1002 have been further modified. Specifically, FIG. 12 illustrates an instance in which the bend angle 1106 has been changed to 100 degrees (e.g., from 90 degrees, as shown in FIG. 11) and in which the bend radius 1110 has been changed to 1.3 mm (from 1 mm, as shown in FIG. 11). In the example shown in FIG. 12, manual selection of the bend radius 1110 has been activated, and predetermined bend radius options 1202 for the manually selected bend radius 1110 are presented in the form of a dropdown menu. In some implementations, the predetermined bend radius options 1202 are constrained by at least some of the manufacturing configurations (e.g., die configurations) available to the one or more specific manufacturing facilities (or one or more designated manufacturing facilities) for which an order for manufacture of the sheet metal part 206 (or a modified sheet metal part based thereon) can be sent (e.g., after user interaction with order placement functionality within a user interface as described herein). The predetermined bend radius options 1202 can be additionally or alternatively constrained by the selected material 902.

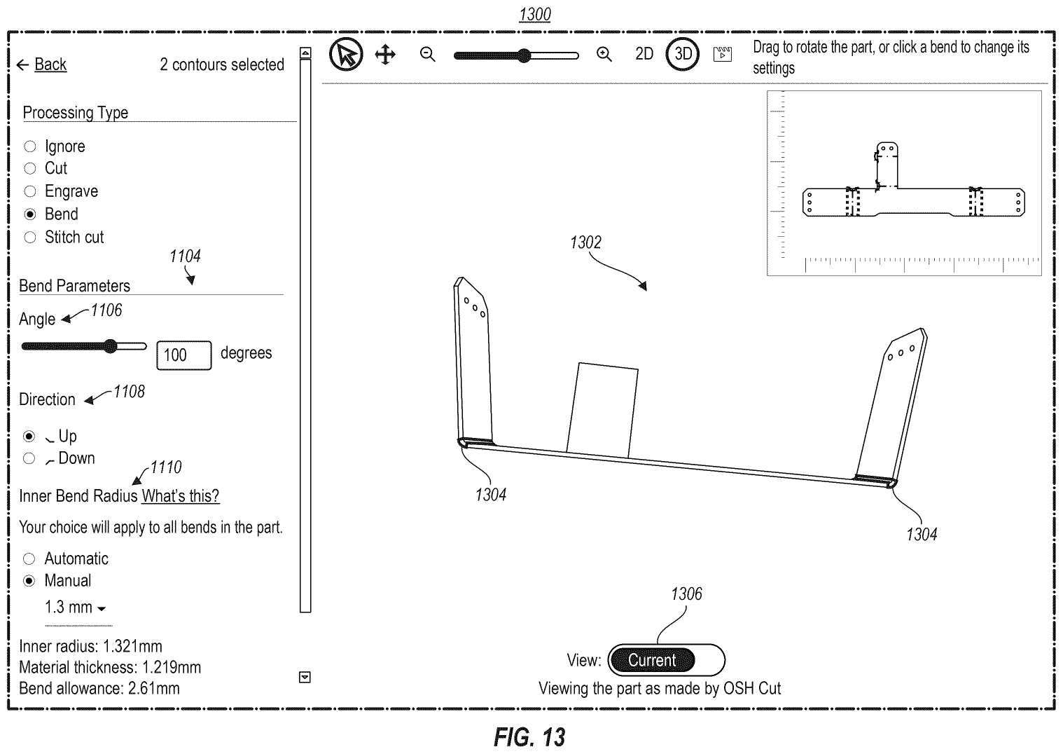

In some instances, a modified sheet metal part (based on the sheet metal part 206 and/or the selected material 902) can be updated or generated further based on user selection or modification of the characteristics 1104 of the various bends of a modified flat pattern 1002 (or flat pattern 402), such as the bend angle 1106 and bend radius 1110 modifications described above for the bends 1102 with reference to FIG. 12. FIG. 13 illustrates an example user interface display 1300 that includes a 3D representation of a modified sheet metal part 1302 that captures the modifications to the characteristics 1104 of the bends 1102 discussed above with reference to FIG. 12. For instance, the modified sheet metal part 1302 of the user interface display 1300 includes bends 1304, which correspond to bends 1102 described above. As is shown in the user interface display 1300 of FIG. 13, the bend angle 1106 of the bends 1304 of the modified sheet metal part 1302 is 100 degrees, and the bend radius 1110 of the bends 1304 is 1.3 mm.

The user interface display 1300 of FIG. 13 depicts the bends 1304 of the modified sheet metal part 1302 as highlighted or otherwise emphasized (e.g., with coloring) in 3D form. In some instances, bends may be selectable in different representations of a sheet metal part, and the selection of bends can persist when transitioning between different representations of a sheet metal part or modified sheet metal part (e.g., 3D representation, flat pattern representation, simulation representation, etc.).

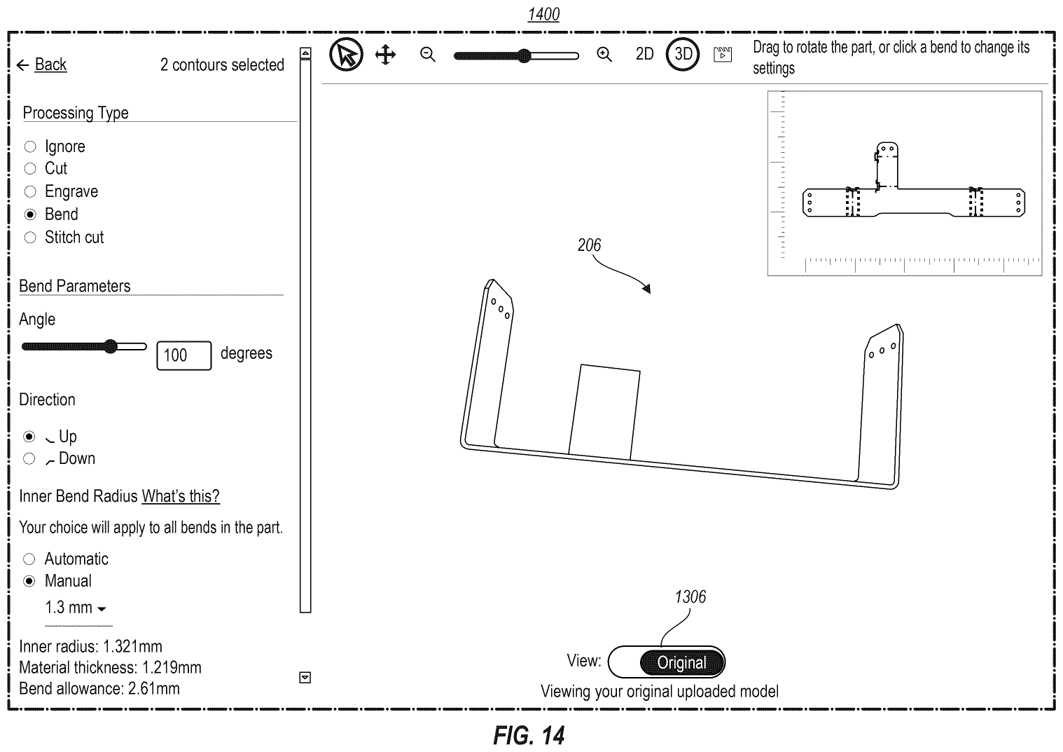

In the example of FIG. 13, the user interface display 1300 includes a toggle element 1306, which can be used to alternate between depicting the original sheet metal part 206 (e.g., according to the input file 202) and the modified sheet metal part 1302. FIG. 14 illustrates an example user interface display 1400 that depicts the sheet metal part 206 in 3D form, which may be triggered by selection of the toggle element 1306 of the user interface display 1300 as described above. Such functionality can enable users to readily ascertain difference between a sheet metal part (e.g., sheet metal part 206) as originally provided (e.g., in the input file 202) and a modified sheet metal part (e.g., modified sheet metal part 1302). Additionally, or alternatively, a system may be configured to simultaneously present a depiction of a sheet metal part as originally uploaded/provided and a depiction of a modified sheet metal part based thereon (e.g., after modifications triggered by material selection and/or user modifications to sheet metal part characteristics).

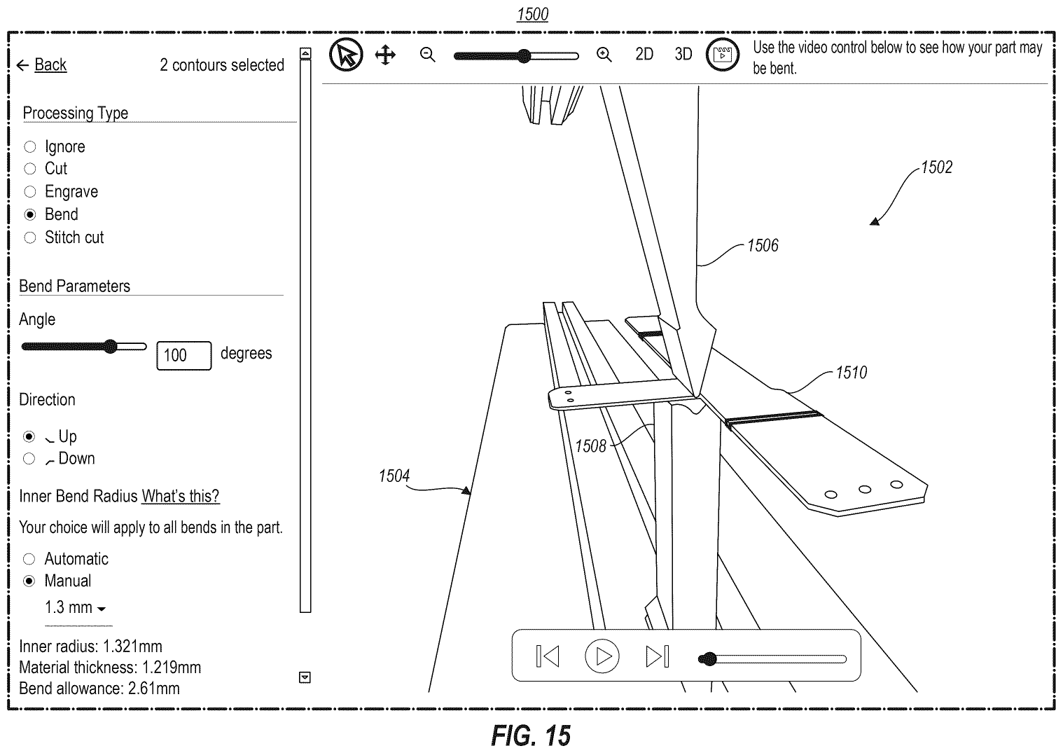

FIGS. 15, 16, and 17 illustrate example user interface displays 1500, 1600, and 1700, respectively, that include a manufacturing simulation 1502 for the modified sheet metal part 1302. The manufacturing simulation 1502 depicts a press brake machine 1504 with a punch 1506 and a die 1508 connected to facilitate bending of a blank 1510 that corresponds to the modified flat pattern 1002. In the manufacturing simulation 1502, multiple bending steps/operations can be shown to visually illustrate movement of the press brake machine 1504 to press the blank 1510 into contact with the die 1508 to facilitate bending of the blank 1510 to form the modified sheet metal part 1302 (e.g., in accordance with the selected material 902, the user-driven modifications to bend characteristics, etc.). The manufacturing simulation 1502 can depict different manufacturing configurations for different bending steps/operations (e.g., different machines, punches, dies, etc.).

The specific manufacturing configurations shown throughout the bending steps/operations of the manufacturing simulation 1502 can be selected based on DFM processes performed for the modified sheet metal part 1302, which may be performed after generation of the modified sheet metal part 1302 (e.g., based on material selections and/or modifications made to bend characteristics as described above with reference to FIGS. 9 through 12). For instance, the manufacturing simulation 1502 can visually depict the manufacturing configuration(s) for different bending operations/steps that are determined to avoid or minimize manufacturing errors after iteratively applying virtual bending operations using multiple different manufacturing configurations available to one or more designated manufacturing facilities, as described above.

In some implementations, aspects of the manufacturing configurations used for the virtual bending operations (e.g., used in the DFM processing) are influenced by the user modifications to or selections of bend characteristics of the modified sheet metal part 1302. For instance, a user selection or modification of the bend angle 1106 can constrain or affect selection of the punch configuration(s) used in the virtual bending operations. As another example, a user selection or modification of the bend radius 1110 can constrain or affect selection of the die configuration(s) used in the virtual bending operations.

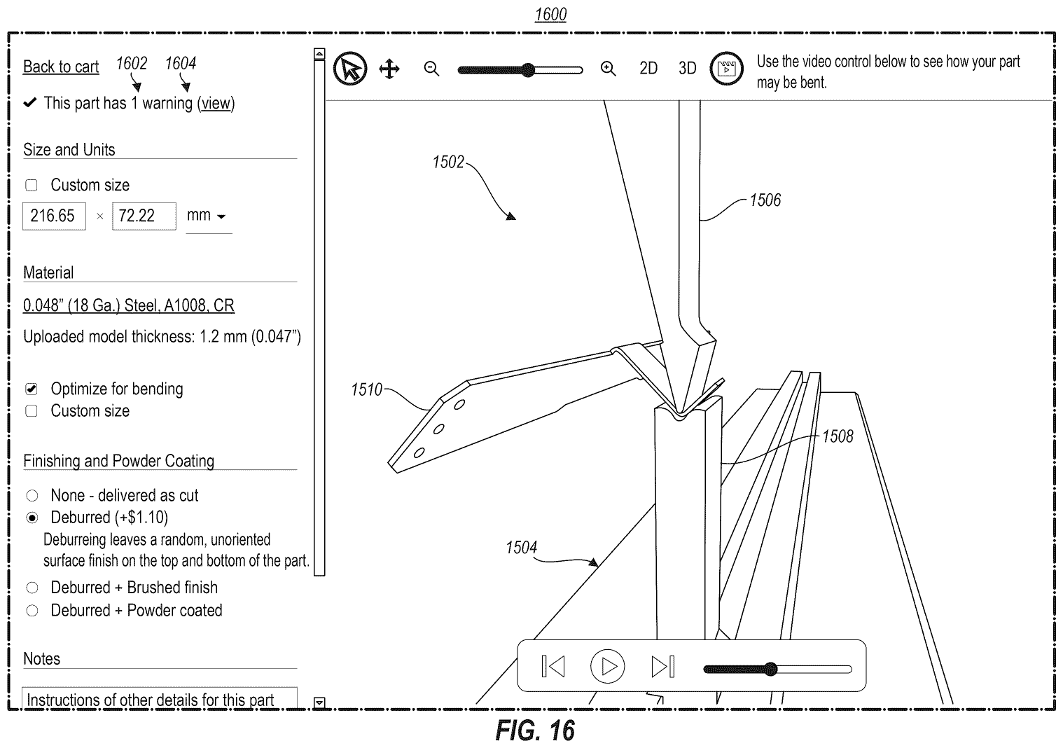

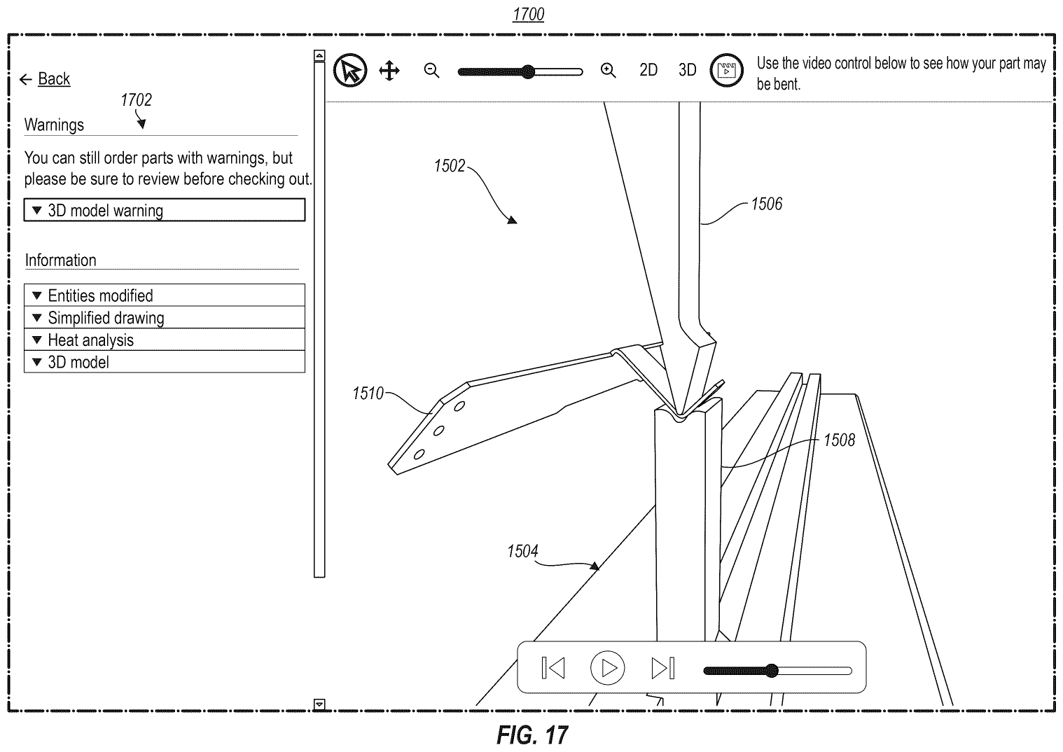

FIG. 16 depicts a manufacturability indicator 1602 indicating whether the modified sheet metal part 1302 is manufacturable based on the DFM processes performed to determine the manufacturability thereof. In the example shown in FIG. 16, the manufacturability indicator 1602 indicates that the part has 1 warning and provides the user with a selectable element 1604 to access more details related to the warning. FIG. 17 illustrates a manufacturability indicator 1702 with additional details related to the warning (e.g., displayed after selection of the selectable element 1604 of FIG. 16). In particular, the manufacturability indicator 1702 of FIG. 17 indicates that parts with warnings are still manufacturable using the manufacturing configurations against which the modified sheet metal part 1302 was tested (and which are available to the designated manufacturing facility/facilities that would receive an order for manufacture of the modified sheet metal part 1302 if placed by the user via the checkout element 306). The manufacturability indicator 1702 also indicates the nature of the warning with a collapsible banner, which indicates that the warning applicable to manufacture of the modified sheet metal part 1302 is a 3D model warning (e.g., warning the user that modifications were made to the sheet metal part 206 as represented in the input file 202 based on selected material 902 and/or user-driven modifications to part characteristics, and that the user should review the changes before moving forward with order placement).

A manufacturability indicator (e.g., manufacturability indicators 1602 or 1702) for a modified sheet metal part 1302 may provide different indications based on the outcomes of the DFM performed for the modified sheet metal part 1302 (e.g., the manufacturability indicator can indicate that the design check has been passed or that no errors or warnings exist, similar to the manufacturability indicator 1004 described above, or the manufacturability indicator can indicate additional or alternative warnings, or the manufacturability indicator can indicate one or more errors, similar to the manufacturability indicators 302, 404, 502, or the manufacturability indicator can indicate a combination of warnings and errors). Furthermore, a manufacturability indicator for a modified sheet metal part 1302 may indicate problem regions for detected warnings or errors (e.g., collision regions, regions that have low or insufficient flange support, etc.) in various presentation modalities (e.g., flat pattern presentations, 3D part presentations, manufacturing simulation presentations, etc.).

In the example manufacturing simulation 1502 shown in FIGS. 15, 16, and 17, the punch 1506 can be selected based on the user selection or modification of the bend angle 1106, as described hereinabove with reference to FIGS. 11 and 12 (e.g., different bend angles can trigger a change in punch configuration to avoid collisions during manufacturing). For instance, and for illustrative purposes, the manufacturing simulation 1502 can comprise a different punch 1506 than the punch 706 shown in conjunction with the manufacturing simulation 702, where different bend angles are used (e.g., compare FIGS. 7 and 15). In some implementations, the die 1508 shown in the manufacturing simulation 1502 can be selected based on user selection or modification of the bend radius 1110, as described hereinabove with reference to FIGS. 11 and 12. For instance, and for illustrative purposes, the manufacturing simulation 1502 can comprise a different die 1508 than the die 708 shown in conjunction with the manufacturing simulation 702, where different bend radii are used (e.g., compare FIGS. 7 and 15).

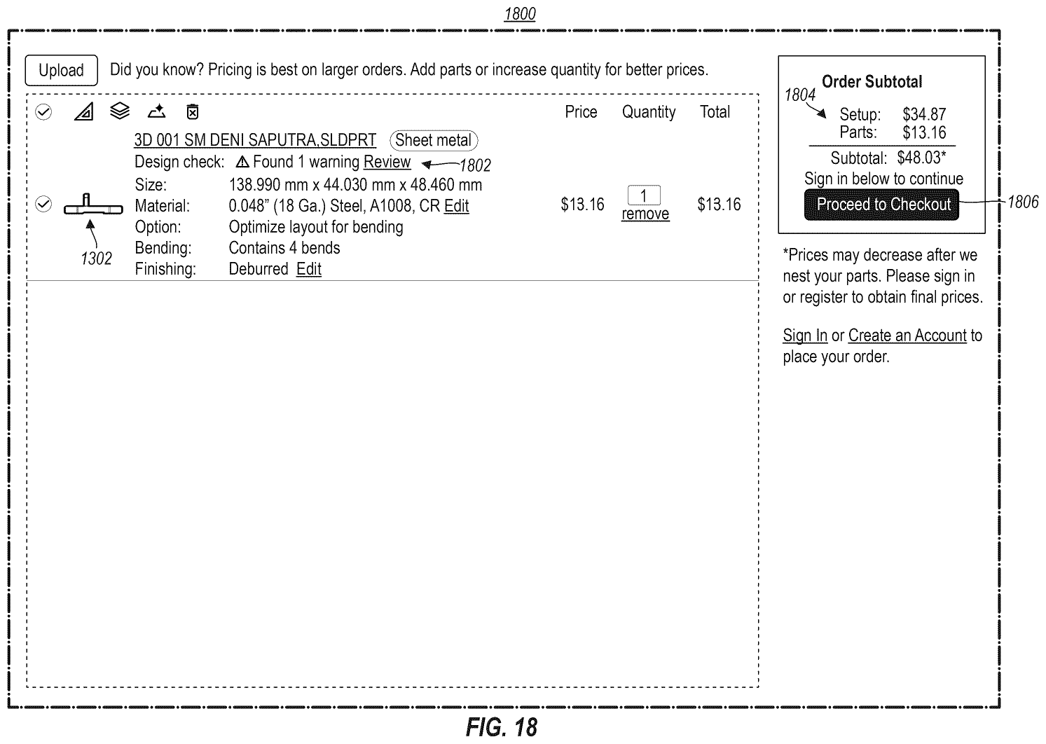

FIG. 18 illustrates an example user interface display 1800 that is similar to the user interface display 300 discussed hereinabove with reference to FIG. 3. For instance, the user interface display 1800 includes a manufacturability indicator 1802 indicating the manufacturability of the modified sheet metal part 1302 as discussed above. The user interface display 1800 also includes a price region 1804 and a checkout element 1806. In contrast with the price region 304 of FIG. 3, the price region 1804 is populated or updated with price information associated with manufacture of the modified sheet metal part 1302, which can be enabled based on the manufacturability indicator 1802 indicating that the modified sheet metal part 1302 is manufacturable (or based on the DFM processing that informs the manufacturability indicator 1802). Similarly, in contrast with the checkout element 306 of FIG. 3, the checkout element 1806 can be enabled based on the manufacturability indicator 1802 indicating that the modified sheet metal part 1302 is manufacturable (or based on the DFM processing that informs the manufacturability indicator 1802), which can enable order placement functionality for users to trigger manufacturing of the modified sheet metal part 1302 by one or more designated manufacturing facilities (e.g., which are configured to receive orders placed via the checkout element 1806).

The price listed in the price region 1804 can be updated based on the particular manufacturing configuration(s) selected for manufacture of the modified sheet metal part 1302 by the designated manufacturing facility/facilities that will receive the order if the user proceeds with order placement via the checkout element 1806. For instance, the price listed in the price region 1804 can be determined based on the particular punch configuration(s), particular die configuration(s), particular back gauge configuration(s), particular bend sequence configuration(s), particular machine selection configuration(s), and/or particular part orientation configuration(s) for performing the various bend steps/operations at the designated manufacturing facility/facilities to form the modified sheet metal part 1302 in a manner that avoids collisions or other manufacturing errors, as determined by the DFM processing as noted above.

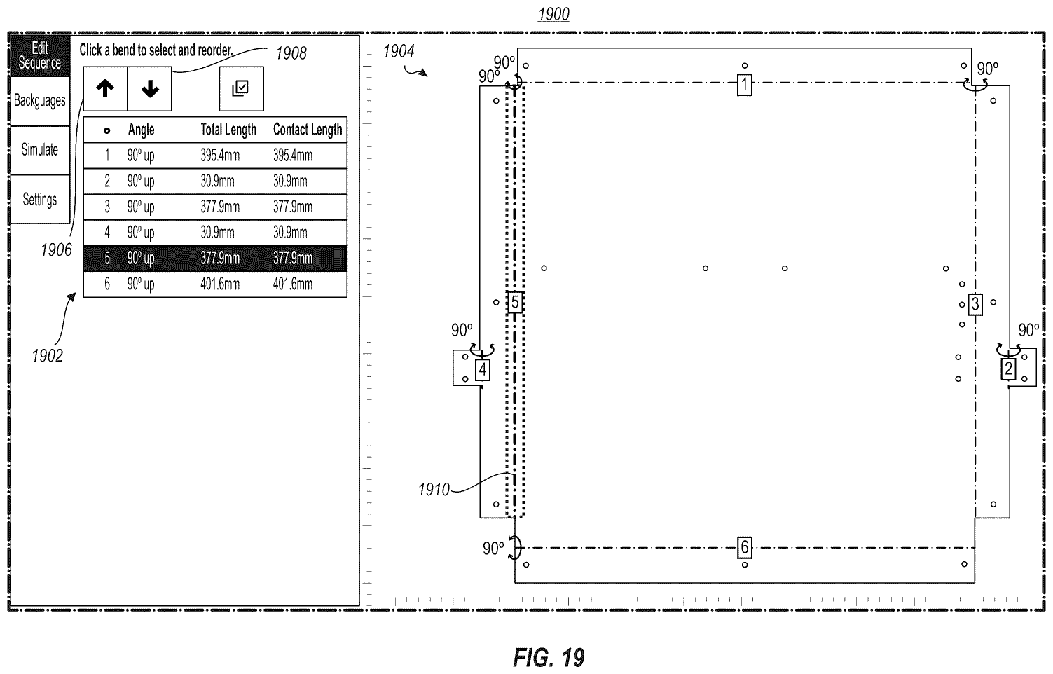

In some implementations, users may access or modify additional or alternative manufacturing configurations available to one or more designated manufacturing facilities (e.g., facilities configured to receive orders placed) for manufacturing custom sheet metal parts. FIGS. 19, 20, 21, and 22 illustrate additional manufacturing configurations that can be presented to users in association with a sheet metal part (e.g., represented in an input file, which can be provided by the user as discussed hereinabove with reference to FIG. 1) or a modified sheet metal part (e.g., generated based on material or characteristic selection or modification for an initially provided sheet metal part). In some implementations, additional manufacturing configurations similar to those shown and described with reference to FIGS. 19, 20, 21, and 22 are provided when specifically requested (e.g., for advanced users) or after an uploaded sheet metal part is determined to not be manufacturable via DFM processing. By presenting additional manufacturing configurations, users may receive additional information as to why a part is determined not to be manufacturable, which can allow users to experiment with different configurations to approach or achieve manufacturability, and/or which can inform user decisions with respect to redesigning a part for manufacturability.

FIG. 19 illustrates an example user interface display 1900 that includes a bend sequence configuration 1902 for manufacturing a sheet metal part 1904 (illustrated as a flat pattern in the user interface display 1900). The bend sequence configuration 1902 of the user interface display 1900 comprises a visualization of the ordering of bending operations (e.g., represented in the user interface display 1900 as individual list items of the bend sequence configuration 1902). The ordering can be selectively adjustable by a user (e.g., by providing user input at a system presenting the user interface display 1900). For instance, the user interface display 1900 includes ordering buttons 1906 and 1908, which may be selected to change the ordering of the bend sequence configuration 1902. By way of example, FIG. 19 illustrates the fifth bending operation of the bend sequence configuration 1902 in a highlighted or emphasized form, indicating that the fifth bending operation is in a selected state (e.g., the bend 1910 corresponding to the fifth bending operation is also emphasized in the custom sheet metal part 1904). With the fifth bending operation of the bend sequence configuration 1902 in the selected state, selection of the ordering buttons 1906 or 1908 can cause reordering of the bending operation. Other input modes for changing the ordering are within the scope of the present disclosure (e.g., drag and drop). In some instances, bending operations can be provided in the bend sequence configuration 1902 in a granular manner (e.g., with different bends along the same line being listed individually; enabling ordering of partial bends, etc.).

In the example bend sequence configuration 1902 of the user interface display 1900, the individual list items representing individual bend operations are associated with respective information, including order number (represented by the “#” symbol), bend angle, total length, and contact length. In some implementations, additional or alternative information is provided for each of the bending operations. For instance, the machine selection, punch, and/or die for each of the bending operations may be presented in the user interface display 1900 in association with each of the list items of the bend sequence configuration 1902, and such parameters may be selectively modifiable by users (in accordance with configurations available to the designated manufacturing facility/facilities).

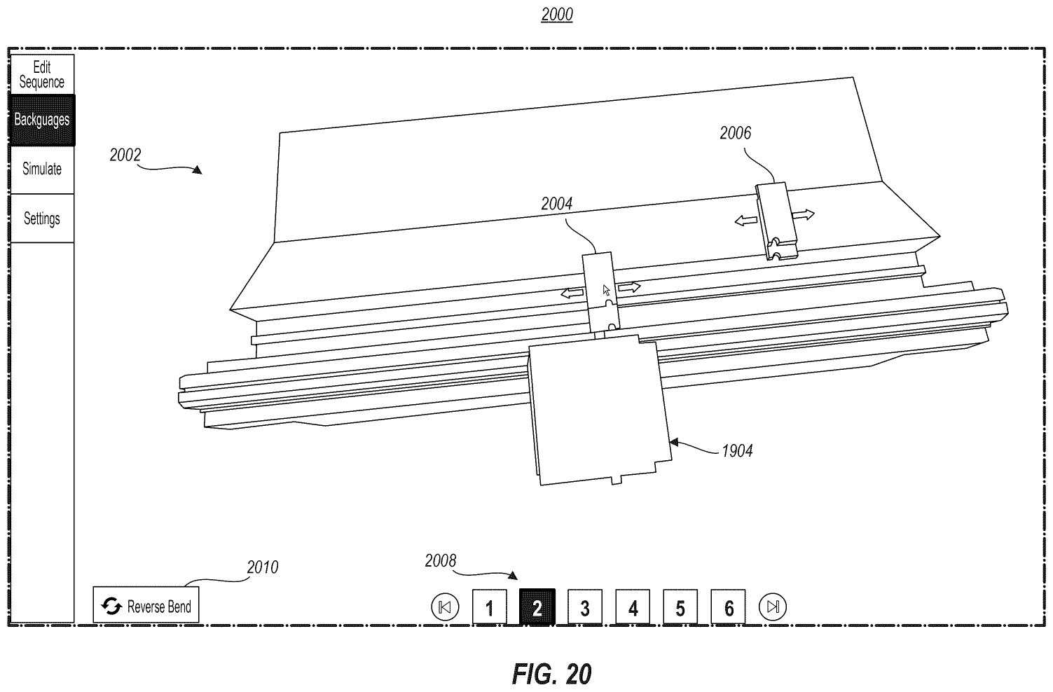

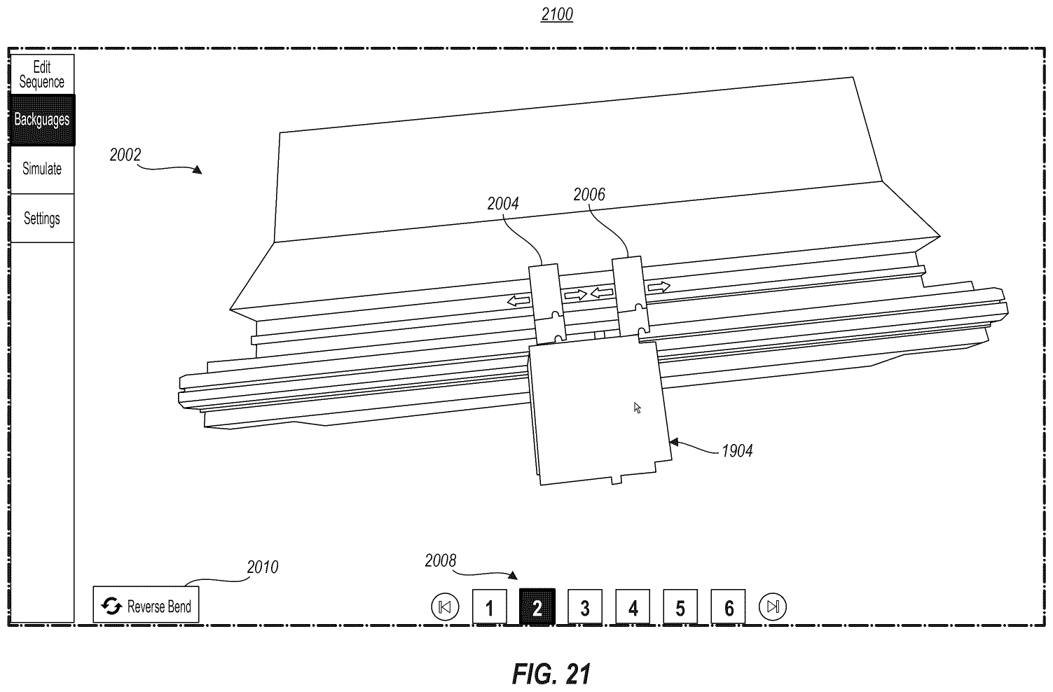

FIGS. 20 and 21 illustrate example user interface displays 2000 and 2100, respectively, that include a back gauge configuration 2002 for manufacturing the sheet metal part 1904. The back gauge configuration 2002 shown in FIGS. 20 and 21 comprises a visualization of the placement of back gauges 2004 and 2006 during bending operations (characteristics of the back gauges 2004 and 2006 may be defined by the machine selection discussed above with reference to FIG. 19). For instance, the user interface display 2000 and the user interface display 2100 show a bending operation index 2008 with numbered items corresponding to the different bending operations of the bend sequence configuration 1902 discussed hereinabove with reference to FIG. 19. Users may navigate to different bending operations via the bending operation index 2008 to access the back gauge configuration for the selected bending operation.

In FIGS. 20 and 21, the second bending operation of the bending operation index 2008 (corresponding to the second list item of the bend sequence configuration 1902) is selected for analysis, giving rise to the back gauge configuration 2002 shown in the user interface displays 2000 and 2100. The back gauge configuration 2002 shown in the user interface display 2000 provides an initial configuration of the back gauges 2004 and 2006 (e.g., a configuration selected via DFM processing, as described herein). A user may provide control input (e.g., click/tap and drag input, or other types) directed to the back gauges 2004 and/or 2006 within the user interface display 2000 to selectively change the configuration of the back gauges 2004 and/or 2006 for the second bending operation of the bending operation index 2008 (positional adjustment of the back gauges 2004 and 2006 may be guided by object snap functionality to assist users in aligning the back gauges 2004 and 2006 with the sheet metal part 1904). The back gauge configuration 2002 of the user interface display 2100 of FIG. 21 illustrates a modified position of the back gauges 2004 and 2006 with respect to the sheet metal part 1904 for the second bending operation, which may occur after user input is detected modifying the positioning of the back gauges 2004 and 2006 for the second bending operation.

The user interface displays 2000 and 2100 also include an orientation element 2010, which can be selectable by users to achieve changes in the orientation of the sheet metal part 1904 for the selected bending operation of the bending operation index 2008. For instance, selection of the orientation element 2010 can cause a 180 degree rotation of the sheet metal part 1904 about its out-of-plane axis or Z-axis within the user interface displays 2000 and/or 2100.

In accordance with the discussion of FIGS. 19, 20, and 21, a user may provide user input to define one or more aspects of a particular manufacturing configuration for individual bend operations for forming a sheet metal part 1904. The particular manufacturing configuration can include a particular bend sequence configuration 1902, machine selection configuration, punch configuration, die configuration, back gauge configuration 2002, and/or part orientation configuration for each of the bending operations. In some instances, the punch configuration and/or the die configuration available for selection are constrained by a bend angle and/or a bend radius selected via user input (as described herein with reference to FIGS. 11, 12, and 13). DFM processing may be performed using the particular manufacturing configuration to determine whether the sheet metal part 1904 is manufacturable using the particular manufacturing configuration (e.g., by applying virtual bending operations to a flat pattern based on the sheet metal part 1904 using the particular manufacturing configuration). Based on the outcome of the DFM processing, one or more indications of manufacturability may be presented to the user (e.g., similar to one or more of manufacturability indicators 302, 404, 502, 1004, 1602, 1702, and/or 1802). In some implementations, when the DFM processing indicates that the sheet metal part 1904 is manufacturable by the designated manufacturing facility/facilities, pricing information for manufacturing the sheet metal part 1904 can be automatically determined, updated, and/or presented, and/or order placement functionality for ordering manufacture of the sheet metal part 1904 from the designated manufacturing facility/facilities may be selectively enabled (e.g., similar to the user interface display 1800 of FIG. 18). In some instances, after an order is placed for manufacture of the sheet metal part 1904, the particular manufacturing configuration may be sent to the designated manufacturing facility/facilities along with the order, which may enable laborers to reference a working configuration for manufacturing the sheet metal part 1904.

In some instances, if the DFM processing indicates that the sheet metal part 1904 is not manufacturable by the designated manufacturing facility/facilities, an indication of non-manufacturability may be presented (e.g., similar to manufacturability indicators 302, 404, and/or 502), which may indicate one or more problem regions associated with manufacturing the 1904 using the particular manufacturing configuration.

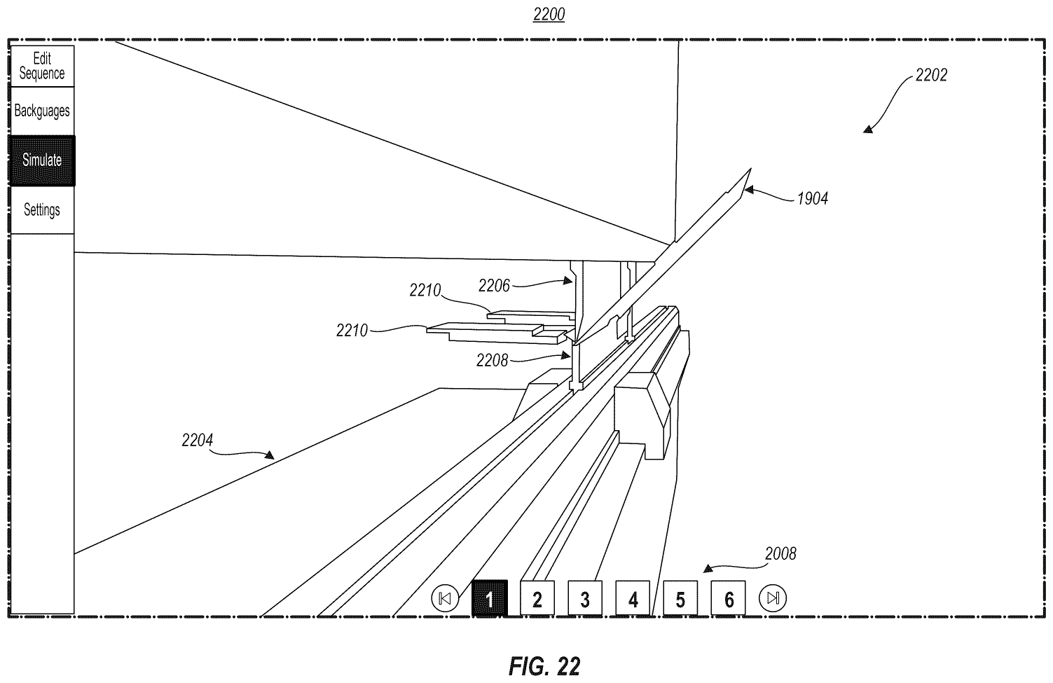

The virtual bending operations of the DFM processing using the particular manufacturing configuration may additionally be presented to the user. For instance, FIG. 22 illustrates an example user interface display 2200 that includes a manufacturing simulation 2202 for the sheet metal part 1904. The manufacturing simulation 2202 depicts a press brake machine 2204 with one or more punches 2206, dies 2208, and back gauges 2210 to facilitate formation of the sheet metal part 1904. The manufacturing simulation 2202 depicts operation of the press brake machine 2204 and its components to show bending operations for forming the sheet metal part 1904. In the example shown in FIG. 22, the user interface display 2200 also includes the bending operation index 2008 to indicate to the user which bending operation is being visually depicted. The press brake machine 2204 and one or more punches 2206, dies 2208, and back gauges 2210, as well as their configurations, shown in the manufacturing simulation 2202 can be determined by the user-defined particular manufacturing configuration discussed hereinabove with reference to FIGS. 19, 20, and 21 (recognizing that different press brake machines, punches, dies, back gauges, and/or configurations thereof can be used for different bending operations).

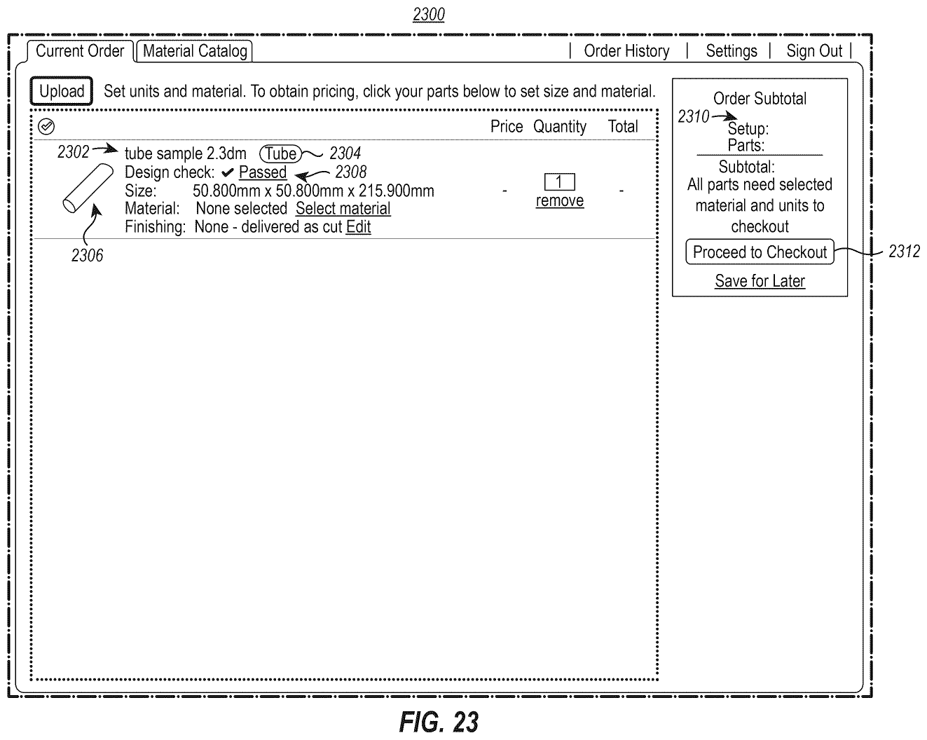

Referring again to the user interface display 100 of FIG. 1, in some implementations, the input file submitted by the user (e.g., interacting with the user interface display 100) can include a representation of a metal tubing part (e.g., a custom metal tubing part). FIG. 23 illustrates an example user interface display 2300 that conceptually depicts an input file 2302 (by reference to its name) as well as a type label 2304 that states “tube”. The input file can be preprocessed (e.g., using server and/or local resources) to determine whether the input file 2302 includes a representation of a metal tubing part (or another type of part, such as a sheet metal part). The type label 2304 can be defined and/or presented based on the outcome of such preprocessing.

FIG. 23 conceptually depicts the metal tubing part 2306 represented by the input file 2302 (by showing a thumbnail depiction thereof). FIG. 23 also depicts a manufacturability indicator 2308 (or an “indication of manufacturability”) for the metal tubing part 2306 represented by the input file 2302. The manufacturability indicator 2308 can be conceptually similar to other manufacturability indicators described herein. For instance, the manufacturability indicator 2308 can take on various forms and can indicate whether the metal tubing part 2306 is manufacturable by one or more designated manufacturing facilities and/or can provide various types of other information (e.g., problem regions, warnings, recommended modifications, etc.). In the example shown in FIG. 23, the manufacturability indicator 2308 indicates (for illustrative purposes) that no manufacturing errors exist (by stating “Passed”), which can indicate that the metal tubing part 2306 is manufacturable by the one or more designated manufacturing facilities.

The label associated with the manufacturability indicator 2308 can be determined based on DFM processing performed for the metal tubing part 2306. DFM processing for a metal tubing part can comprise applying one or more manufacturing rules to the metal tubing part, where the manufacturing rules are based on manufacturing configurations available to the one or more designated manufacturing facilities (e.g., the manufacturing facility/facilities that would receive and/or fulfill an order if placed by the user). In this regard, the manufacturing configurations used for the manufacturing rules can be based on inventory-specific and/or machine-specific data associated with the designated manufacturing facility or facilities, which can be dynamically updated to reflect current conditions (e.g., to reflect changes in material, tooling, or machine availability, etc.). In some implementations, the manufacturing rules constrain bevel angle, tooling access (e.g., whether a laser or other cutting device can be positioned to form the features of the metal tubing part), bevel consistency (e.g., whether partial bevels or discontinuous bevels exist in the metal tubing part), metal tubing length, cut clearance (e.g., whether the exit surface or underside for a cut has sufficient clearance to avoid undesired cuts/features), and/or cut depth (e.g., whether partial depth cuts exist in the metal tubing part).

DFM processing for a metal tubing part can be performed for a modified metal tubing part that is generated based on the metal tubing part 2306 represented by the input file 2302 submitted by the user. For example, after selection of a material for manufacturing the metal tubing part 2306, a modified metal tubing part may be generated using attributes of the selected material and attributes of the metal tubing part 2306 represented by the input file 2302 (e.g., adapting the thickness of the selected material with the overall diameter of the metal tubing part 2306; modifying bend radii in square, rectangular, or angled tubes based on material attributes; etc.). DFM processing may then be performed on the modified metal tubing part, and a manufacturability indicator may be generated or updated based on the DFM processing to communicate to the user whether the modified metal tubing part is manufacturable to the user.

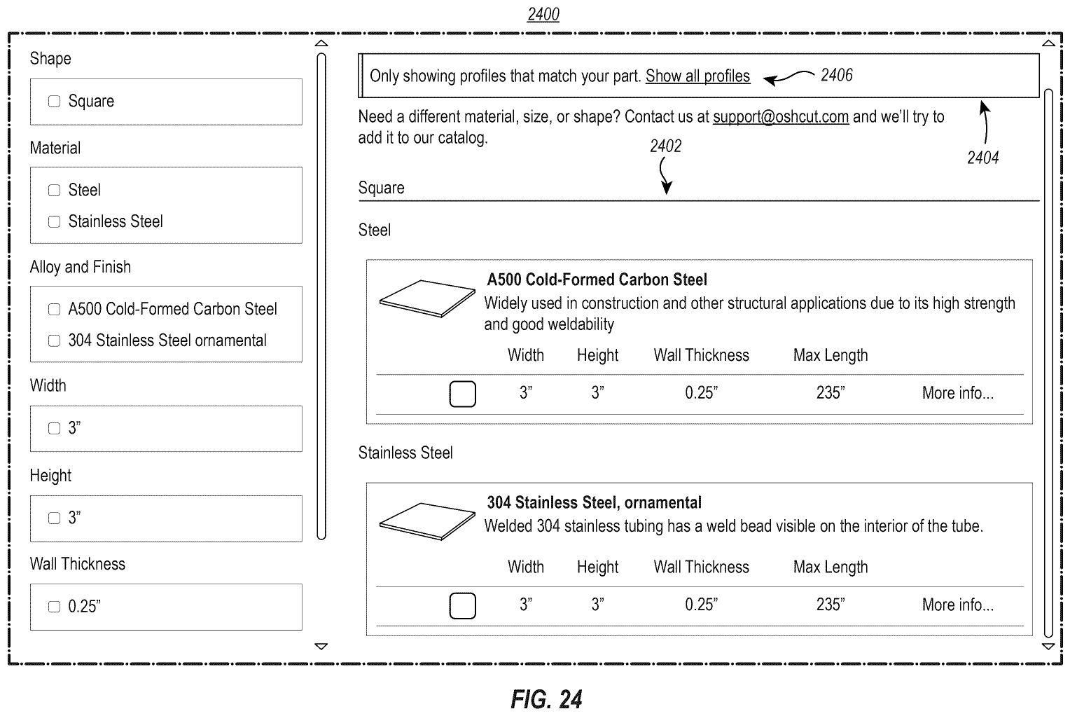

FIG. 24 illustrates an example user interface display 2400 for obtaining a material selection for manufacture of a metal tubing part 2306 (e.g., a materials interface). The user interface display 2400 can provide various filtering options, such as the shape of the material, the alloy and finish of the material, the width, the height, the wall thickness, etc. In the example shown in FIG. 24, the user interface display 2400 also includes an indicator 2404 that indicates filtering of the materials presented based on their profile similarity to the metal tubing part 2306 represented by the input file 2302. For example, a system (e.g., using server and/or local resources) can obtain a metal tubing profile based on the metal tubing part 2306 as represented by the input file 2302. The metal tubing profile can be obtained in various ways, such as by fitting profile shapes to one or more faces of the metal tubing part 2306 represented by the input file 2302 (e.g., in a manner that accounts for partial profiles or for cuts made in the metal tubing part 2306), by utilizing machine learning techniques (e.g., using template matching, feature-based matching, geometric hashing, contour matching, convolutional neural networks, and/or others), by receiving user input (e.g., indicating a profile face, wall thickness, diameter, length, etc.), combinations of these, and/or others. Candidate metal tubing materials may then be determined by comparing the metal tubing profile to a set of known tubing materials. The candidate metal tubing materials can be selected based on the similarity of their profile characteristics to the metal tubing profile extracted from the metal tubing part 2306 represented by the input file 2302. For instance, the candidate metal tubing materials can be selected as those with profile characteristics that satisfy a threshold similarity to the diameter, shape, corner radius, and/or wall thickness associated with the metal tubing profile of the metal tubing part 2306. In some instances, wall thickness is omitted from similarity consideration (e.g., focusing on diameter and/or shape), which can permit the candidate metal tubing materials presented to the user to capture materials with variations in wall thickness that preserve the overall size of the metal tubing part 2306 and/or to capture materials with variations in shape features, such as variations in inside and/or outer radius of the corners of square, rectangular, or other angled metal tubing. In some instances, filtering of the candidate materials presented based on profile similarity can be disabled (e.g., via selection of element 2406).

In some instances, the candidate metal tubing materials may be selected from the metal tubing materials that are in stock at the one or more designated manufacturing facilities. In some instances, the candidate metal tubing materials may be selected from metal tubing materials that are not in stock at the one or more designated manufacturing facilities (e.g., materials that can be acquired by the designated manufacturing facility/facilities upon request/ordering). When determined, the candidate metal tubing materials may be presented on a user interface (e.g., candidate metal tubing materials 2402 presented on the user interface display 2400) so as to enable user selection of a particular metal tubing material.

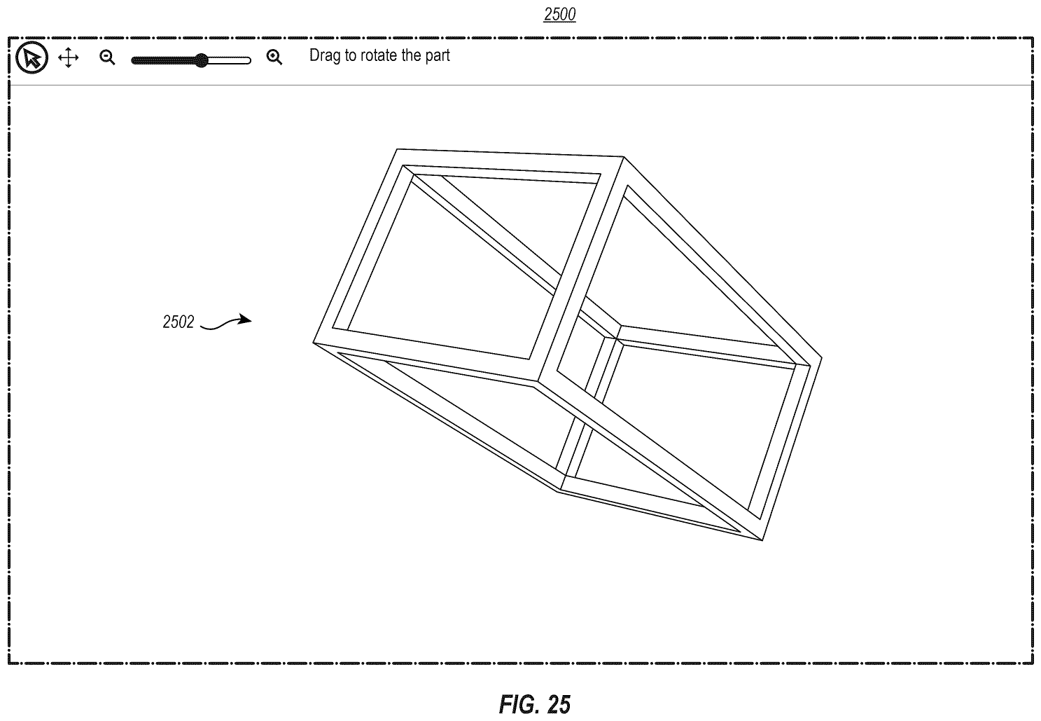

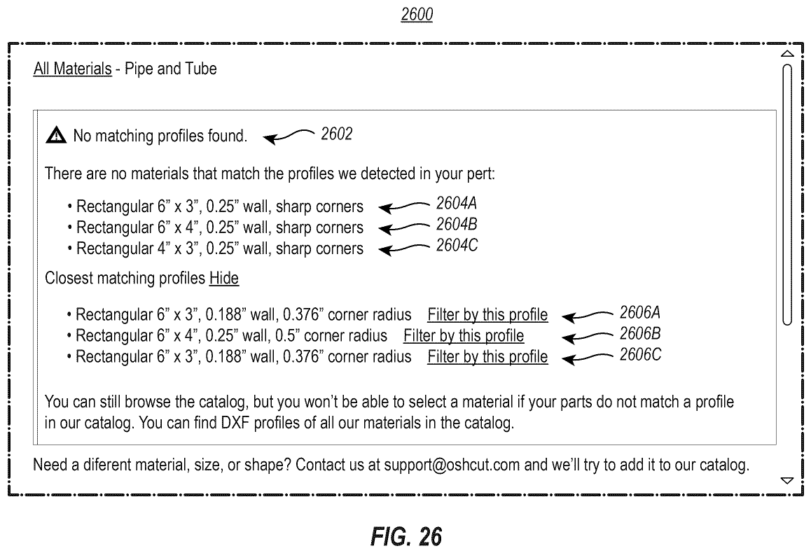

In some instances, a metal tubing part represented by an input file can have multiple candidate profiles on different faces thereof. For instance, FIG. 25 illustrates an example user interface display 2500 showing a metal tubing part 2502 associated with an input file (e.g., similar to input file 2302) provided by a user. The metal tubing part 2502 comprises different profiles that may be assessed for matching with metal tubing materials as described above. After receiving an input file that includes a metal tubing part with multiple potential profiles (e.g., similar to metal tubing part 2502), the system may analyze each potential profile (e.g., relative to the available metal tubing materials) to determine whether a material is available for manufacturing the metal tubing part. For instance, FIG. 26 illustrates an example user interface display 2600 illustrating a case where no matching (or sufficiently similar) materials were found after analyzing the different profiles of the metal tubing part 2502. For instance, the user interface display 2600 includes an indication 2602 that no matching profiles were found, further indicating the different profiles 2604A, 2604B, and 2604C of the metal tubing part 2502 that were analyzed. In the example shown in FIG. 26, the user interface display 2600 presents closest matching profiles 2606A, 2606B, and 2606C for the different profiles 2604A, 2604B, and 2604C, which can provide users with an understanding of the magnitude of differences between the profiles of the metal tubing part 2502 and available materials.

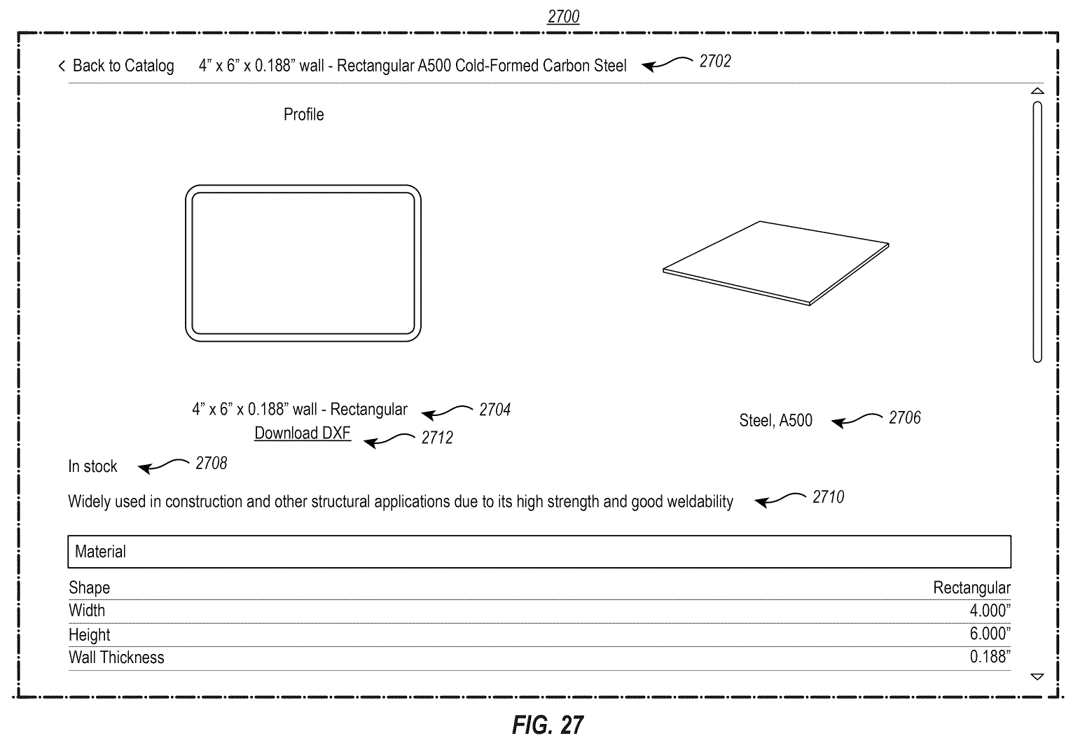

In some implementations, a user can select a material based on one or more closest matching profiles for further analysis and/or comparison to a metal tubing part represented in an input file (e.g., metal tubing part 2502). FIG. 27 illustrates an example user interface display 2700 displaying characteristics of a selected closest matching material, such as name 2702, profile 2704, base material 2706, availability 2708, description 2710, etc. In the example shown in FIG. 27, the user interface display 2700 provides a selectable element 2712 for triggering a download of a drawing or model file corresponding to the selected closest matching material, which can assist users with redesigning their metal tubing part to match an available material.

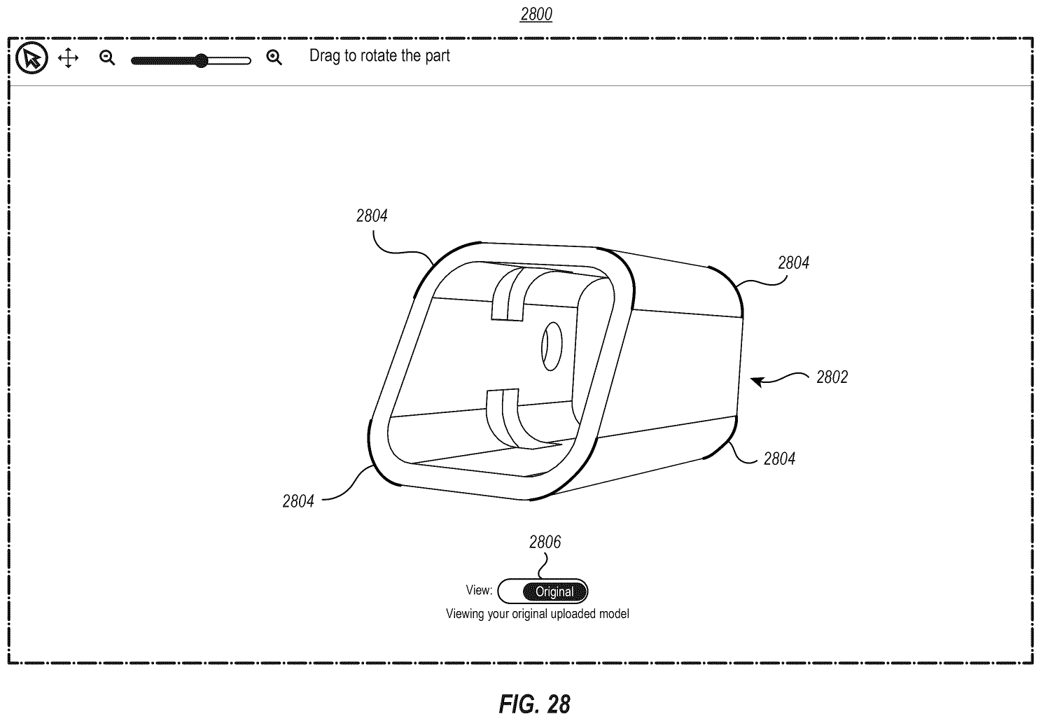

In some implementations, a system as disclosed herein can be configured to display a representation of a metal tubing part corresponding to an input file provided or uploaded by a user. For example, FIG. 28 illustrates example user interface display 2800 illustrating a metal tubing part 2802 as originally uploaded by user or as originally represented in an input file. The metal tubing part 2802 can be displayed on the user interface display 2800 (e.g., in 3D) such that the user can modify the presentation thereof (e.g., by zooming, panning, rotating, etc.). In some implementations, a user interface display that shows a metal tubing part can include a manufacturability indicator (e.g., similar to manufacturability indicator 502). DFM processing may be automatically performed on the metal tubing part 2802, which can provide a basis for a manufacturability indicator.

In one or more embodiments, when DFM processing performed on the metal tubing part 2802 indicates that the metal tubing part 2802 is manufacturable by the one or more designated manufacturing facilities, pricing information for manufacturing the metal tubing part 2802 can be automatically determined, updated, and/or presented, and/or order placement functionality for ordering manufacture of the metal tubing part 2802 from the designated manufacturing facility/facilities may be selectively enabled (e.g., at the price region 2310 and checkout element 2312 shown in FIG. 23, similar to the user interface display 1800 of FIG. 18).

In some instances, when differences exist between the profile of the metal tubing part 2802 and the profile of available or selected metal tubing materials (e.g., differences that meet or exceed one or more difference thresholds), the system may present a profile mismatch indicator (which may be part of a manufacturability indicator). In response to such differences, the system can additionally selectively refrain generating or updating pricing information for the user and can selectively refrain from enabling order placement functionality.

In some implementations, where a selected or available metal tubing material is sufficiently similar to the metal tubing part 2802, the system may generate a modified metal tubing part based on the metal tubing part 2802 and the selected or closest matching material. The modified metal tubing part may be presented on a user interface display, allowing the user to view the original metal tubing part 2802 and the modified metal tubing part to observe differences. In some implementations, where a modified metal tubing part can be generated using an available or selected material, the system can selectively enable order placement functionality for the modified metal tubing part.

For instance, in the example shown in FIG. 28, the metal tubing part 2802 is not manufacturable due to its profile not exactly matching a selected or available material. For instance, FIG. 28 visually emphasizes the corner radii 2804 of the metal tubing part 2802 (e.g., with bolded lines, in the example shown in FIG. 28), indicating that the corner radii 2804 comprise problem regions causing the metal tubing part 2802 to be non-manufacturable. However, the profile of the metal tubing part 2802 may be sufficiently similar to an available material such that a modified metal tubing part may be generated that preserves characteristics (e.g., outer diameter or overall size) of the metal tubing part 2802 while conforming to the available material.

The user interface display 2800 shown in FIG. 28 includes a toggle element 2806 (similar to toggle elements 1306 and others described herein above), enabling the user to switch between a display of the originally uploaded metal tubing part 2802 and a modified metal tubing part (enabling the original metal tubing part 2802 and the modified metal tubing part to be alternately presented). In some implementations, the original metal tubing part and the modified metal tubing part may be presented simultaneously on a user interface display. Such functionality can enable users to readily ascertain differences between an original metal tubing part and a modified metal tubing part (e.g., to show differences in wall thickness, corner radii, etc.).

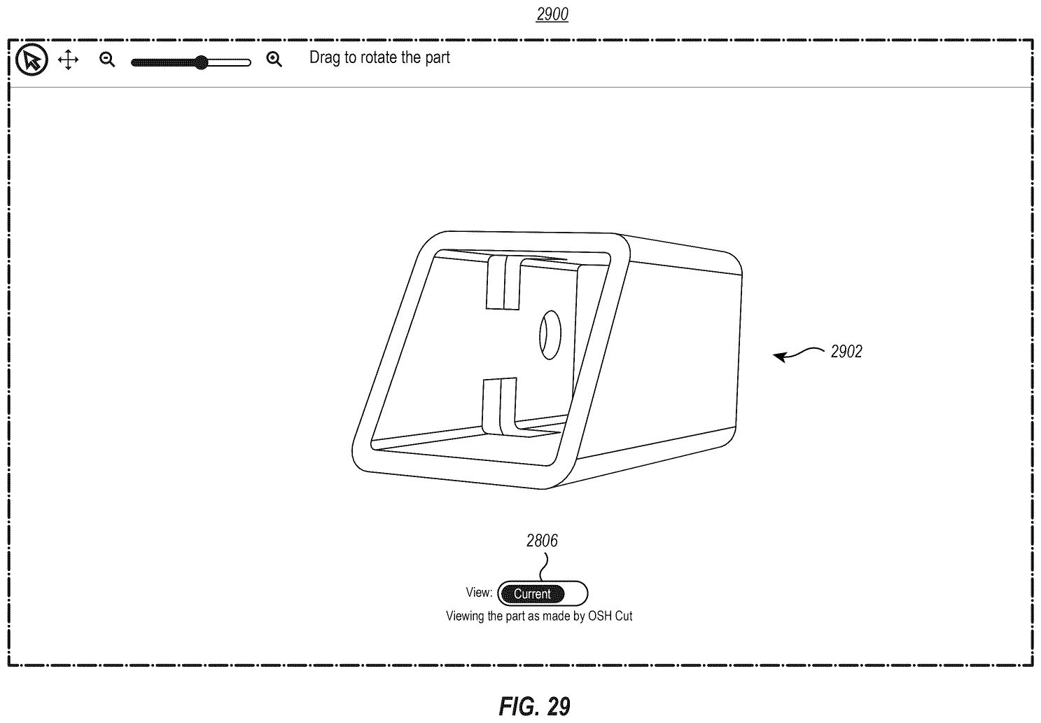

FIG. 29 illustrates an example user interface display 2900 showing a modified metal tubing part 2902 generated based on the originally uploaded metal tubing part 2802 (e.g., after selection of the toggle element 2806). As illustrated in FIG. 29, the modified metal tubing part 2902 includes modified corner radii (based on corner radii for the selected/available material) relative to the corner radii 2804 shown for the metal tubing part 2802 in FIG. 28, while preserving the cuts and overall size of the metal tubing part 2802.

Similar to the metal tubing part 2802, DFM processing may be performed on the modified metal tubing part 2902 to ensure manufacturability. After determining that the modified metal tubing part 2902 is manufacturable, the system may present a manufacturability indicator indicating that the modified metal tubing part 2902 is manufacturable (e.g., in the user interface display 2900 and or other user interface displays), automatically update price, and selectively enable order placement functionality for the modified metal tubing part 2902. In contrast, if the modified metal tubing part 2902 is determined not to be manufacturable (e.g., for reasons other than profile mismatch), the system may present a manufacturability indicator indicating that the modified metal tubing part 2902 is not manufacturable, refrain from updating price, and refrain from enabling order placement functionality for the modified metal tubing part 2902.

Although the example shown and described with reference to FIGS. 28 and 29 related to generation of a modified metal tubing part based on discrepancies between the corner radii of the metal tubing part as uploaded and the corner radii of the available materials, modified metal tubing parts may be generated based on user-provided metal tubing parts in other scenarios. For instance, a system may generate a metal tubing part based on a difference in wall thickness between a metal tubing part from an input file and a wall thickness of one or more available materials (e.g., while still preserving overall size, outer radius, tube length, cut size and position, etc.).

A system may generate a modified metal tubing part for additional or alternative purposes, such as where a metal tubing part represented in an input file fails to satisfy one or more applicable manufacturing rules, such as bevel consistency (e.g., whether partial bevels or discontinuous bevels exist in the metal tubing part), bevel angle, cut clearance (e.g., whether the exit surface or underside for a cut has sufficient clearance to avoid undesired cuts/features), cut depth (e.g., whether partial depth cuts exist in the metal tubing part), tooling access (e.g., whether a laser or other cutting device can be positioned to form the features of the metal tubing part), metal tubing length, and/or others.

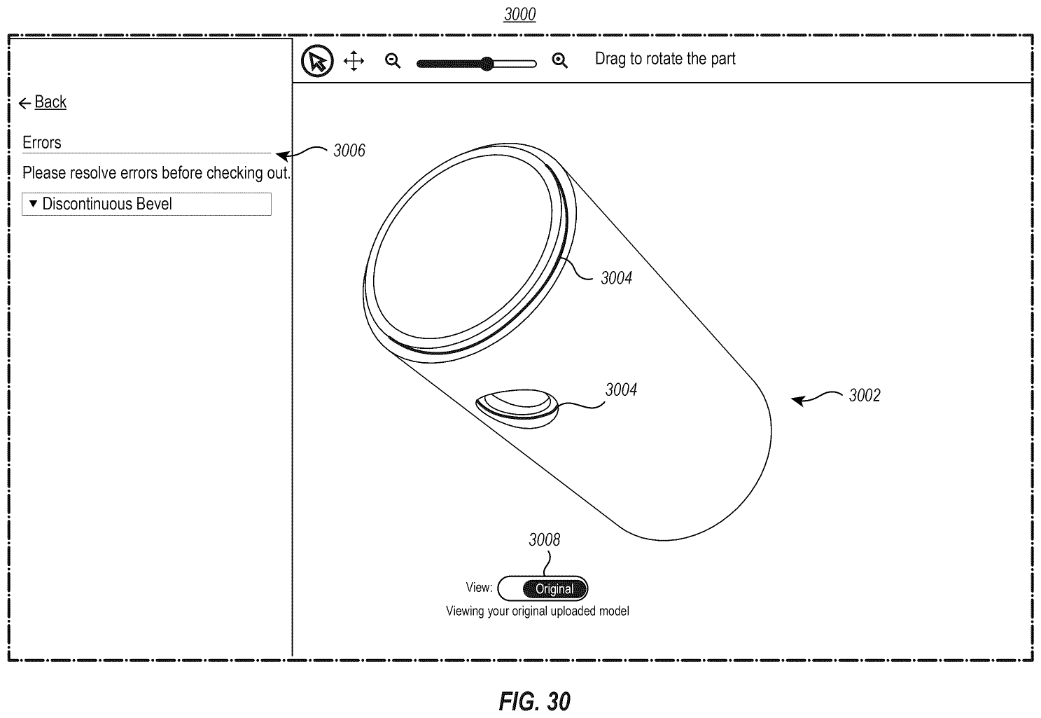

For instance, FIG. 30 illustrates an example user interface display 3000 showing a metal tubing part 3002 corresponding to an input file. The metal tubing part 3002 shown in FIG. 30 includes one or more discontinuous bevels 3004 (e.g., including a step in the bevel), which may violate one or more manufacturing rules associated with one or more relevant manufacturing facilities. In the example shown in FIG. 30, the user interface display 3000 displays the metal tubing part 3002 as including emphasis on the discontinuous bevels 3004 (e.g., in the form of bolded lines), indicating that the discontinuous bevels 3004 comprise a problem region vis-à-vis manufacturability of the metal tubing part 3002. Such functionality can assist users in readily ascertaining the manufacturability issues with the metal tubing part 3002. The user interface display 3000 may include one or more manufacturability indicators 3006 indicating that the metal tubing part 3002 is not manufacturable in its current form. Accordingly, DFM processing performed by the system on the metal tubing part 3002 may cause the system to refrain from updating pricing and/or enabling order placement functionality for the metal tubing part 3002.

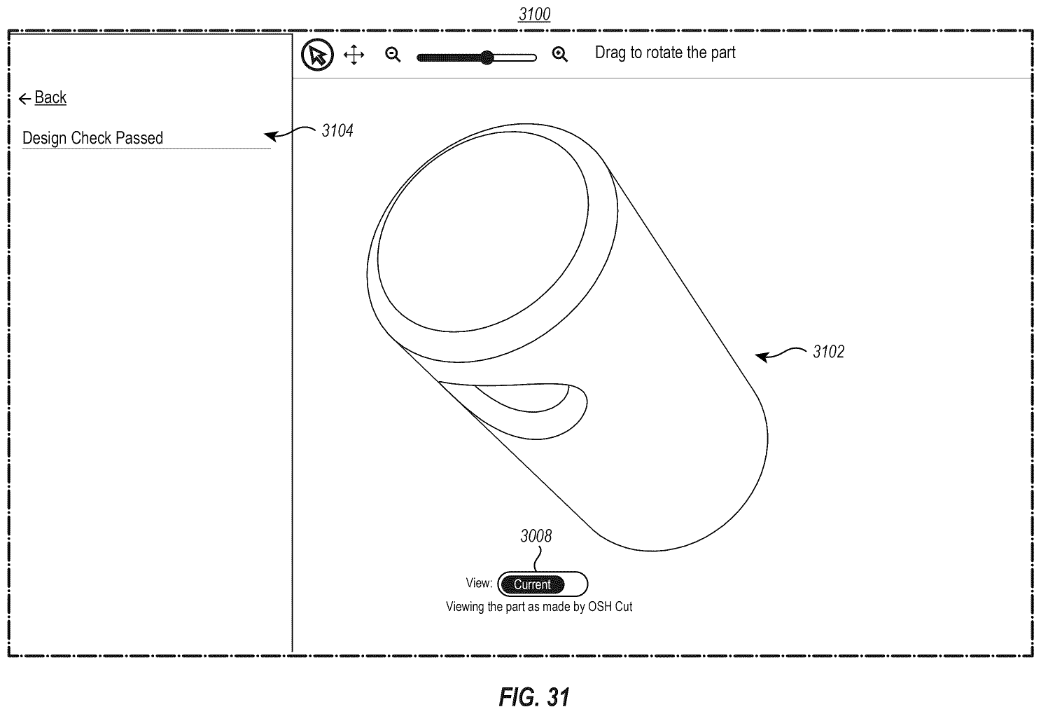

In some implementations, after determining that the metal tubing part 3002 is not manufacturable due to discontinuous bevels, a system may generate (automatically, or after receiving user input) the modified metal tubing part 3102 shown in the user interface display 3100 of FIG. 31 (e.g., which may be presented after selection of toggle element 3008). The modified metal tubing part 3102 shown in FIG. 31 includes modified, continuous bevels (e.g., with the same start and end points as the one or more discontinuous bevels 3004 of the metal tubing part 3002), which may satisfy the applicable manufacturing rules. The modified metal tubing part 3102 may be subjected to DFM processing, and, if the system determines that the modified metal tubing part 3102 is manufacturable, the system may selectively enable order placement functionality and/or update pricing information for the modified metal tubing part 3102. The user interface display 3100 may additionally or alternatively include a manufacturability indicator 3104 indicating that the modified metal tubing part 3102 satisfies the applicable manufacturing rules (and/or is therefore manufacturable via the applicable manufacturing facilities).

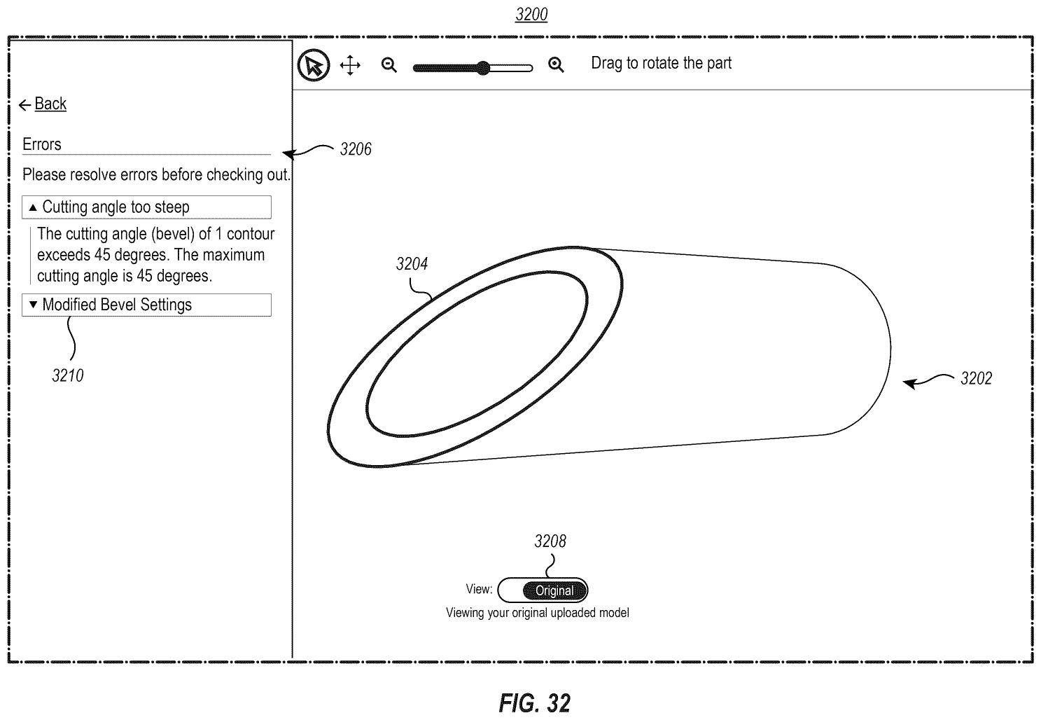

As another example, FIG. 32 illustrates an example user interface display 3200 showing a metal tubing part 3202 corresponding to an input file. The metal tubing part 3202 shown in FIG. 32 includes one or more steep cutting angles 3204 (e.g., or bevel(s)), which may violate one or more manufacturing rules associated with one or more relevant manufacturing facilities (e.g., with a maximum bevel angle of) 45°. In the example shown in FIG. 32, the user interface display 3200 displays the metal tubing part 3202 as including emphasis on the steep cutting angle(s) 3204 of (e.g., in the form of bolded lines), indicating that the steep cutting angle(s) 3204 comprise a problem region vis-à-vis manufacturability of the metal tubing part 3202. The user interface display 3200 may include one or more manufacturability indicators 3206 indicating that the metal tubing part 3202 is not manufacturable in its current form. Accordingly, DFM processing performed by the system on the metal tubing part 3202 may cause the system to refrain from updating pricing and/or enabling order placement functionality for the metal tubing part 3202.

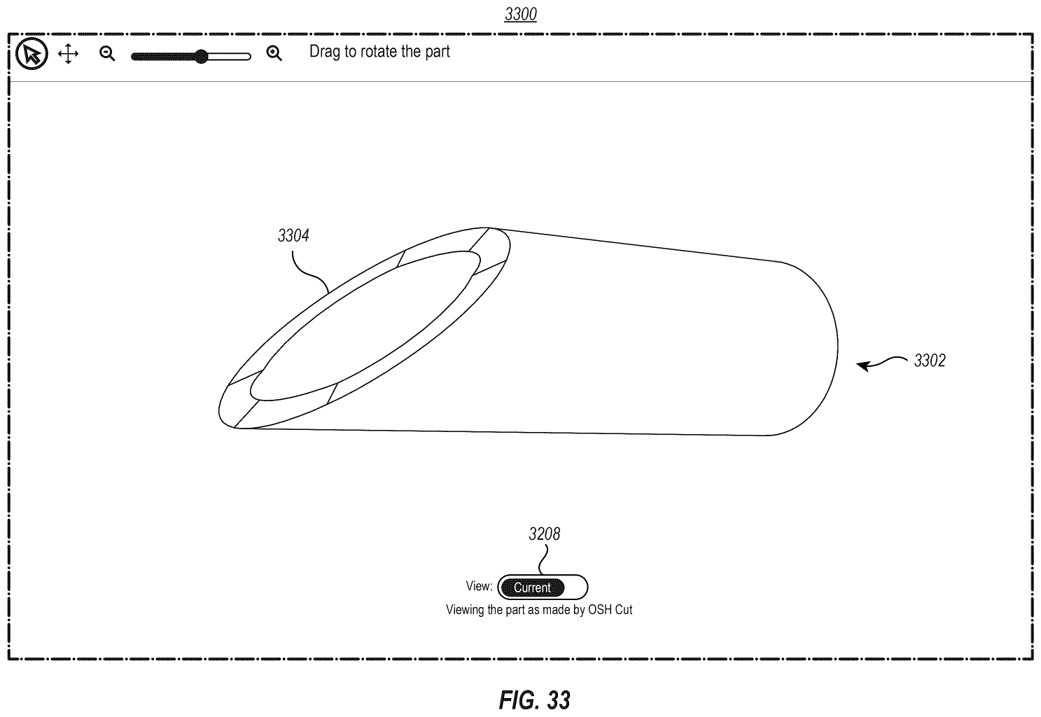

In some implementations, after determining that the metal tubing part 3202 is not manufacturable due to steep bevels (e.g., automatically or based on user input), a system may generate (automatically, or after receiving user input) the modified metal tubing part 3302 shown in the user interface display 3300 of FIG. 33 (e.g., which may be presented after selection of toggle element 3208). The modified metal tubing part 3302 shown in FIG. 33 includes a modified bevel 3304 (e.g., with a reduced bevel angle), which may satisfy the applicable manufacturing rules. The modified metal tubing part 3302 may be subjected to DFM processing, and, if the system determines that the modified metal tubing part 3302 is manufacturable, the system may selectively enable order placement functionality and/or update pricing information for the modified metal tubing part 3302. The user interface display 3300 may additionally or alternatively include a manufacturability indicator indicating that the modified metal tubing part 3102 satisfies the applicable manufacturing rules (and/or is therefore manufacturable via the applicable manufacturing facilities).

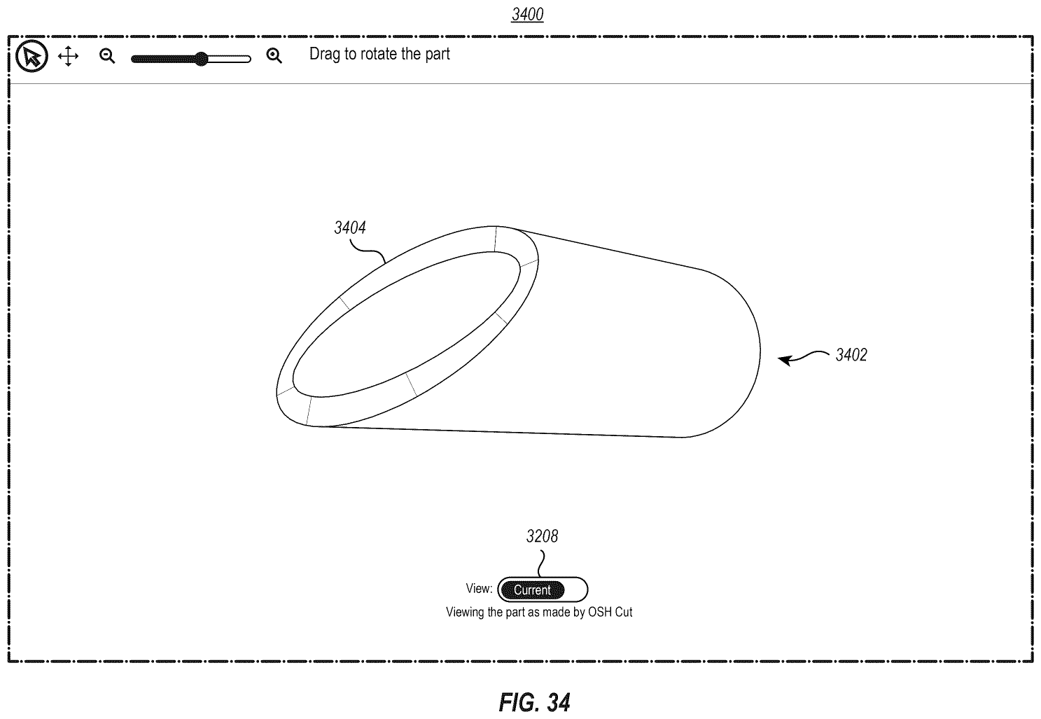

The modified bevel 3304 for the modified metal tubing part 3302 may be determined in various ways. For example, the user interface display 3200 and/or the user interface display 3300 may present one or more controls 3210 allowing users to select characteristics for the modified bevel 3304, such as whether to preserve the location of the original bevel point or the original bevel heel from the metal tubing part 3202 on the modified metal tubing part 3302, or whether to bring both the bevel point and the bevel heel closer together on the modified metal tubing part 3302 relative to the metal tubing part 3202, or whether to implement cut normalization. Different selected settings for a modified bevel may correspond to different modified metal tubing parts generated based on the metal tubing part 3202. For instance, FIG. 34 illustrates a user interface display 3400 showing another modified metal tubing part 3402 generated based on the metal tubing part 3202 that implements cut normalization for the modified bevel 3404 (e.g., where the laser's head orientation maintains a consistent cut angle relative to the outer surface of the modified metal tubing part 3402). In one or more embodiments, a user may select characteristics for the cut normalization used to define the modified bevel 3404 (e.g., via the control(s) 3210), such as whether to user outer edge normalization, inner edge normalization, a combination of outer edge normalization (e.g., closer to the bevel point) and inner edge normalization (e.g., closer to the bevel heel) with one or more transitions (e.g., at the midpoint of the bevel), mid-thickness normalization, etc.

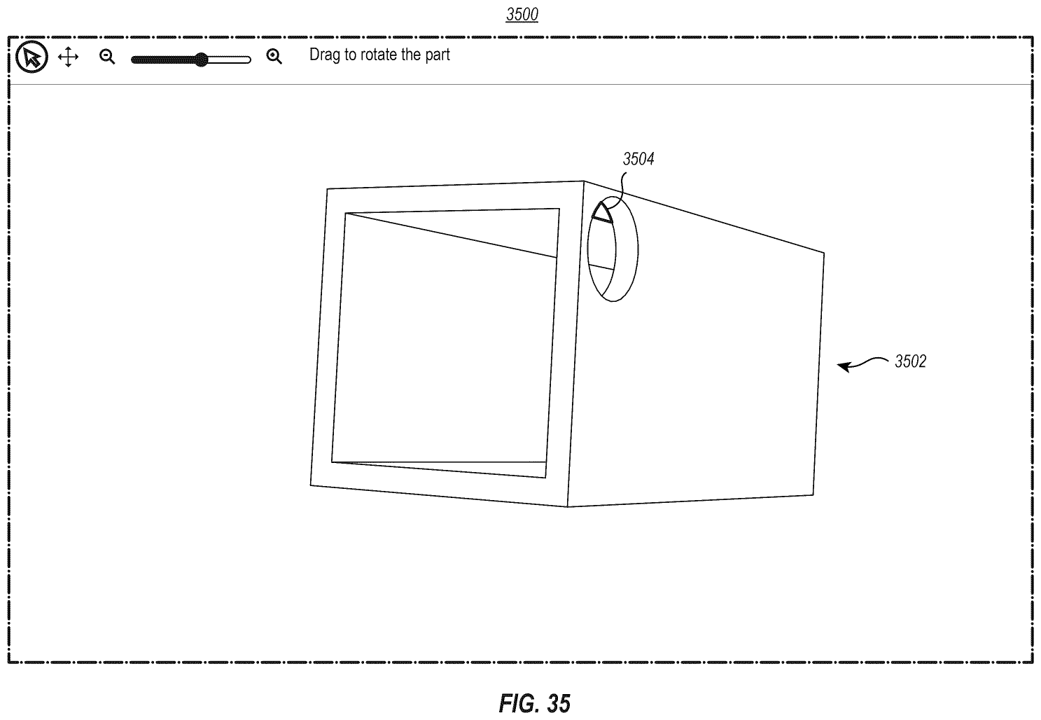

In some implementations, a system refrains from generating a modified metal tubing part in response to DFM processing performed on an original metal tubing part indicating that the metal tubing part is not manufacturable via the relevant manufacturing facilities. For instance, FIG. 35 illustrates an example user interface display 3500 showing a metal tubing part 3502 corresponding to an input file. The metal tubing part 3502 shown in FIG. 35 includes one or more cuts 3504 that lack cut clearance (e.g., lacking an exit surface with sufficient clearance), violating one or more manufacturing rules associated with one or more relevant manufacturing facilities. In the example shown in FIG. 32, the user interface display 3200 displays the metal tubing part 3202 as including emphasis on the portions of the cut(s) 3504 that lack clearance (e.g., in the form of bolded lines), indicating that these portions comprise problem regions vis-à-vis manufacturability of the metal tubing part 3502. The user interface display 3500 may include one or more manufacturability indicators (not shown) indicating that the metal tubing part 3502 is not manufacturable in its current form. DFM processing performed by the system on the metal tubing part 3502 may cause the system to refrain from updating pricing and/or enabling order placement functionality for the metal tubing part 3502. In one or more implementations, the system may refrain from generating a modified metal tubing part based on the metal tubing part 3502.

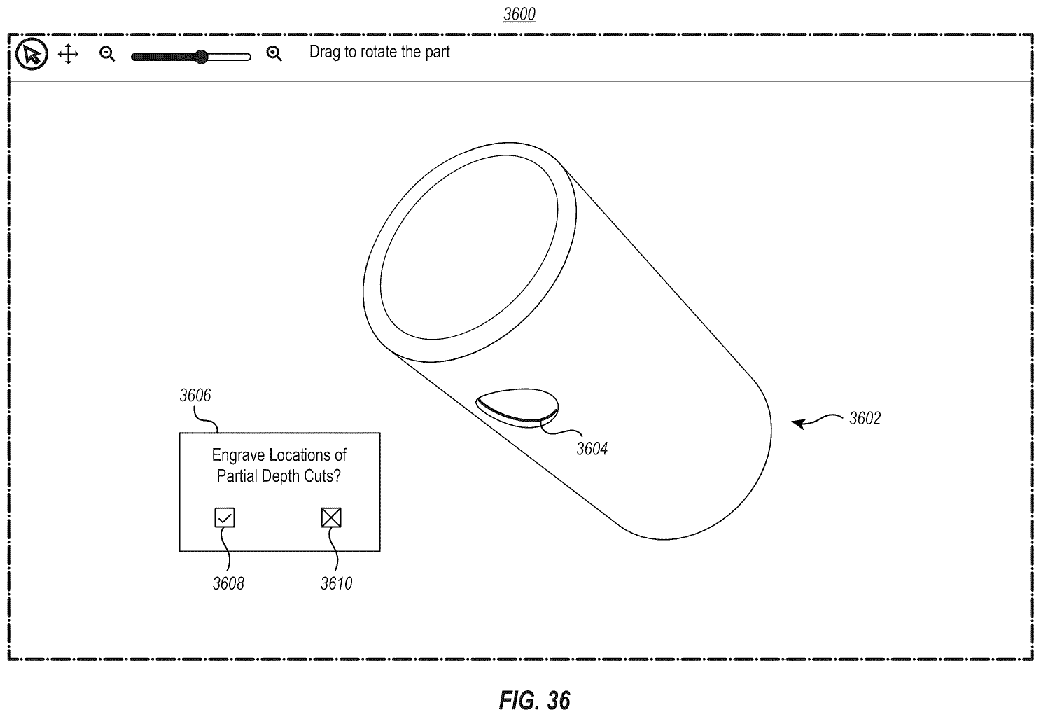

As another example, FIG. 36 illustrates an example user interface display 3600 showing a metal tubing part 3602 corresponding to an input file. The metal tubing part 3602 shown in FIG. 36 includes one or more partial depth cuts 3604, which may violate one or more manufacturing rules associated with one or more relevant manufacturing facilities. In the example shown in FIG. 36, the user interface display 3600 displays the metal tubing part 3602 as including emphasis on the partial depth cut(s) 3604, indicating that these portions comprise problem regions vis-à-vis manufacturability of the metal tubing part 3602. The user interface display 3600 may include one or more manufacturability indicators (not shown) indicating that the metal tubing part 3602 is not manufacturable in its current form. In one or more implementations, the system may refrain from generating a modified metal tubing part based on the metal tubing part 3602.

In some instances, a system may modify cutting instructions or configurations for creation of a metal tubing part corresponding to an originally uploaded or modified metal tubing part. For instance, referring again to the metal tubing part 3602 shown in FIG. 36, the system may present an indicator 3606 on the user interface display 3600 indicating that, although the partial depth cut(s) 3604 are not manufacturable, the system may engrave the location of the partial depth cut(s) 3604 (e.g., using a lower laser cutting setting), enabling customers to complete the partial depth cuts after receiving the metal tubing part manufactured by the relevant manufacturing facility. In one example, the indicator 3606 may enable users to accept or reject the proposal to engrave the locations of the partial depth cut(s) 3604 (e.g., via controls 3608 and 3610) on the metal tubing part 3602 during manufacture. If the user accepts the proposal (e.g., via control 3608), the system may modify the metal tubing part 3602 and/or may couple cutting instructions/configurations to the metal tubing part 3602 to cause engraving (rather than cutting) at the locations of the partial depth cut(s) 3604 during manufacture of the metal tubing part 3602. The system may then update pricing information and/or selectively enable order placement functionality for the metal tubing part 3602 (e.g., provided that the metal tubing part 3602 passes other DFM checks).

If the user rejects the proposal to perform engravings rather than cuts for the partial depth cut(s) 3604 (e.g., via control 3610), the system may refrain from modifying the metal tubing part 3602 and/or refrain from coupling cutting instructions/configurations to the metal tubing part 3602 for engraving of the locations of the partial depth cut(s) 3604. In case of rejection, the system may refrain from updating pricing information and/or enabling order placement functionality for the metal tubing part 3602.

In some instances, a modified metal tubing part may be generated based on one or more user modifications. In one example, a user interface display (e.g., a user interface display 2800, 2900, 3000, 3100, 3200, 3300, 3400, 3500, or 3600) can include a presentation of one or more metal tubing part characteristics that enables user selection or modification of the characteristic(s), and user selection or modification of the characteristic(s) can cause generation of a modified metal tubing part (e.g., similar to the modifications discussed above for sheet metal parts, see FIGS. 11, 12, and 13). In some instances, the metal tubing part characteristics are presented after determining that an original metal tubing part (or a previously generated modified metal tubing part) are not manufacturable (e.g., via DFM processing). Example metal tubing part characteristics that can be presented for user selection or modification can include metal tubing material, bevel angle, bevel consistency, metal tube length, cut depth, cut positioning, and/or others. Similar to modified metal tubing parts generated based on profile comparisons, bevel consistency, bevel angles, or cut depth (as described above), DFM processing can be automatically performed on the modified metal tubing part generated via user selection or modification of metal tubing part characteristics, which can provide a basis for a manufacturability indicator and can influence the generating or updating of pricing information and/or the enablement of order placement functionality.

As indicated above, when the original or modified metal tubing part is determined to be not manufacturable, one or more problem regions of the modified metal tubing part can be emphasized or highlighted within the user interface display (e.g., by highlighting or otherwise emphasizing on the 3D representation of the modified metal tubing part features or bevel angles inaccessible to a cutting tool, cuts that lack clearance, discontinuous bevels, partial depth cuts, length issues).

In some implementations, a system can present a manufacturing simulation of a metal tubing part or a modified metal tubing part (e.g., illustrating movement of a chuck and/or cutting head relative to the metal tubing part or modified metal tubing part to show various cutting operations). The manufacturing simulation can utilize manufacturing configurations available to the designated manufacturing facility or facilities. In some instances, when the modified metal tubing part is determined to be not manufacturable, one or more problem regions of the modified metal tubing part can be emphasized or highlighted within the manufacturing simulation (e.g., by highlighting or otherwise emphasizing on the 3D representation of the modified metal tubing part features or bevel angles inaccessible to a cutting tool, cuts that lack clearance, discontinuous bevels, partial depth cuts, length issues).

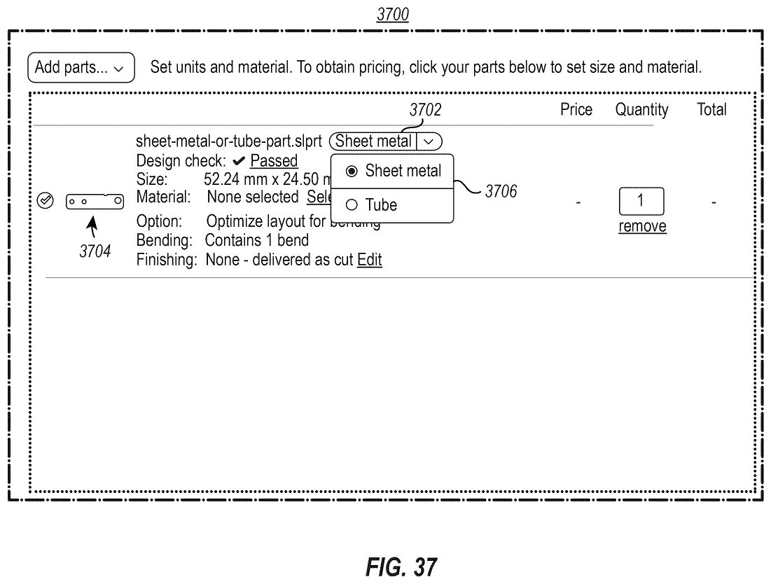

In some implementations, preprocessing performed on a metal part represented in an input file may indicate that the metal part may be potentially manufactured using sheet metal processes or using metal tubing processes. In such instances, a system can be configured to receive user input indicating whether to manufacture the metal part using sheet metal processes or metal tube cutting processes. For example, FIG. 37 illustrates an example user interface display 3700 that may be presented after receiving and preprocessing an input file representing a custom metal part (e.g., after provision of the input file via user interface display 100). The user interface display 3700 includes a type label 3702, similar to type label 204 described above. In the example shown in FIG. 37, the type label 3702 indicates a sheet metal framework for further processing of the metal part 3704. With the type label 3702 indicating sheet metal, various operations may be performed under a sheet metal framework as described hereinabove to facilitate DFM processing, modified part generation, pricing determination, and/or order placement based on the metal part 3704 (e.g., as described hereinabove with reference to FIGS. 4 through 22).

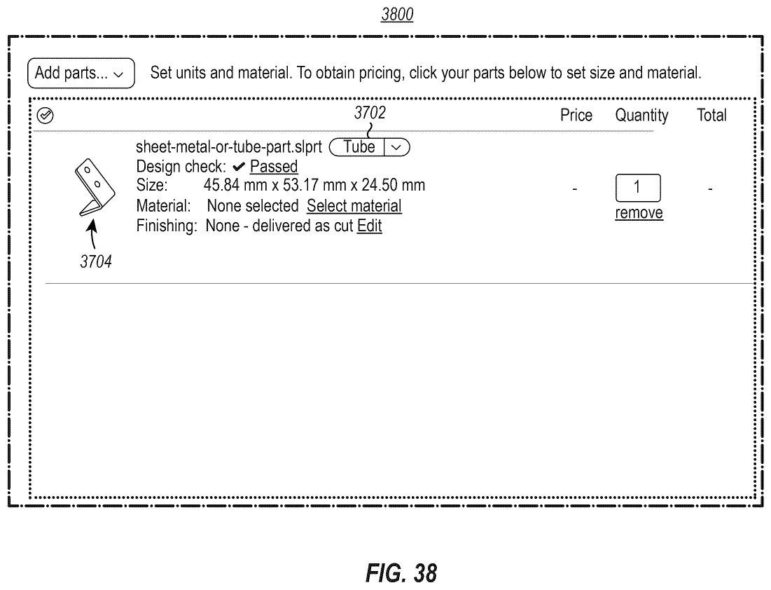

The user interface display 3700 shown in FIG. 37 furthermore includes a selection tool 3706 that allows users to change the type label 3702 for the metal part 3704 (e.g., between sheet metal and metal tubing). The selection tool 3706 may be surfaced or enabled when the metal part represented in the input file is determined, via preprocessing, to be potentially manufacturable using sheet metal processes or metal tubing processes. FIG. 38 illustrates a user interface display 3800 showing the type label 3702 for the metal part 3704 changed (e.g., via the selection tool 3706) to indicate a metal tubing framework for further processing of the metal part 3704. With the type label 3702 indicating metal tubing, various operations may be performed under a metal tubing framework as described hereinabove to facilitate DFM processing, modified part generation, pricing determination, and/or order placement based on the metal part 3704 (e.g., as described hereinabove with reference to FIGS. 24 through 36).

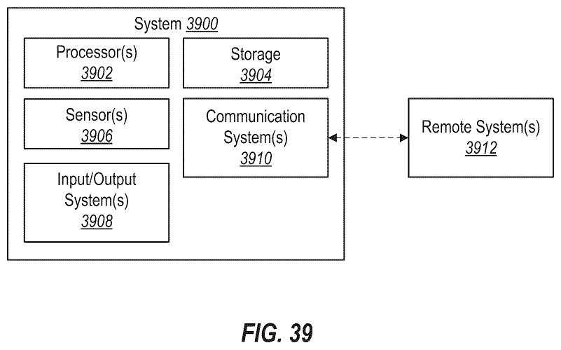

FIG. 39 illustrates example components of a system 3900 that may comprise or implement aspects of one or more disclosed embodiments. For example, FIG. 39 illustrates an implementation in which the system 3900 includes processor(s) 3902, storage 3904, sensor(s) 3906, I/O system(s) 3908, and communication system(s) 3910. Although FIG. 39 illustrates a system 3900 as including particular components, one will appreciate, in view of the present disclosure, that a system 3900 may comprise any number of additional or alternative components.

The processor(s) 3902 may comprise one or more sets of electronic circuitries that include any number of logic units, registers, and/or control units to facilitate the execution of computer-readable instructions (e.g., instructions that form a computer program). Such computer-readable instructions may be stored within storage 3904. The storage 3904 may comprise physical system memory and may be volatile, non-volatile, or some combination thereof. Furthermore, storage 3904 may comprise local storage, remote storage (e.g., accessible via communication system(s) 3910 or otherwise), or some combination thereof. Additional details related to processors (e.g., processor(s) 3902) and computer storage media (e.g., storage 3904) will be provided hereinafter.

As will be described in more detail, the processor(s) 3902 may be configured to execute instructions stored within storage 3904 to perform certain actions. In some instances, the actions may rely at least in part on communication system(s) 3910 for receiving data from remote system(s) 3912, which may include, for example, separate systems or computing devices, sensors, servers, and/or others. The communications system(s) 3910 may comprise any combination of software or hardware components that are operable to facilitate communication between on-system components/devices and/or with off-system components/devices. For example, the communications system(s) 3910 may comprise ports, buses, or other physical connection apparatuses for communicating with other devices/components. Additionally, or alternatively, the communications system(s) 3910 may comprise systems/components operable to communicate wirelessly with external systems and/or devices through any suitable communication channel(s), such as, by way of non-limiting example, Bluetooth, ultra-wideband, WLAN, infrared communication, and/or others.

FIG. 39 illustrates that a system 3900 may comprise or be in communication with sensor(s) 3906. Sensor(s) 3906 may comprise any device for capturing or measuring data representative of perceivable phenomenon. By way of non-limiting example, the sensor(s) 3906 may comprise one or more image sensors, microphones, thermometers, barometers, magnetometers, accelerometers, gyroscopes, and/or others.

Furthermore, FIG. 39 illustrates that a system 3900 may comprise or be in communication with I/O system(s) 3908. I/O system(s) 3908 may include any type of input or output device such as, by way of non-limiting example, a display, a touch screen, a mouse, a keyboard, a controller, and/or others, without limitation.

Disclosed embodiments may comprise or utilize a special purpose or general-purpose computer including computer hardware, as discussed in greater detail below. Disclosed embodiments also include physical and other computer-readable media for carrying or storing computer-executable instructions and/or data structures. Such computer-readable media can be any available media that can be accessed by a general-purpose or special-purpose computer system. Computer-readable media that store computer-executable instructions in the form of data are one or more “physical computer storage media” or “computer-readable recording media” or “hardware storage device(s).” Computer-readable media that merely carry computer-executable instructions without storing the computer-executable instructions are “transmission media.” Thus, by way of example and not limitation, the current embodiments can comprise at least two distinctly different kinds of computer-readable media: computer storage media and transmission media.

Computer storage media (aka “hardware storage device”) are computer-readable hardware storage devices, such as RAM, ROM, EEPROM, CD-ROM, solid state drives (“SSD”) that are based on RAM, Flash memory, phase-change memory (“PCM”), or other types of memory, or other optical disk storage, magnetic disk storage or other magnetic storage devices, or any other medium that can be used to store desired program code means in hardware in the form of computer-executable instructions, data, or data structures and that can be accessed by a general-purpose or special-purpose computer.

A “network” is defined as one or more data links that enable the transport of electronic data between computer systems and/or modules and/or other electronic devices. When information is transferred or provided over a network or another communications connection (either hardwired, wireless, or a combination of hardwired or wireless) to a computer, the computer properly views the connection as a transmission medium. Transmission media can include a network and/or data links which can be used to carry program code in the form of computer-executable instructions or data structures and which can be accessed by a general purpose or special purpose computer. Combinations of the above are also included within the scope of computer-readable media.

Further, upon reaching various computer system components, program code means in the form of computer-executable instructions or data structures can be transferred automatically from transmission computer-readable media to physical computer-readable storage media (or vice versa). For example, computer-executable instructions or data structures received over a network or data link can be buffered in RAM within a network interface module (e.g., a “NIC”), and then eventually transferred to computer system RAM and/or to less volatile computer-readable physical storage media at a computer system. Thus, computer-readable physical storage media can be included in computer system components that also (or even primarily) utilize transmission media.

Computer-executable instructions comprise, for example, instructions and data which cause a general-purpose computer, special purpose computer, or special purpose processing device to perform a certain function or group of functions. The computer-executable instructions may be, for example, binaries, intermediate format instructions such as assembly language, or even source code. Although the subject matter has been described in language specific to structural features and/or methodological acts, it is to be understood that the subject matter defined in the appended claims is not necessarily limited to the described features or acts described above. Rather, the described features and acts are disclosed as example forms of implementing the claims.

Disclosed embodiments may comprise or utilize cloud computing. A cloud model can be composed of various characteristics (e.g., on-demand self-service, broad network access, resource pooling, rapid elasticity, measured service, etc.), service models (e.g., Software as a Service (“SaaS”), Platform as a Service (“PaaS”), Infrastructure as a Service (“IaaS”), and deployment models (e.g., private cloud, community cloud, public cloud, hybrid cloud, etc.).

Those skilled in the art will appreciate that at least some aspects of the invention may be practiced in network computing environments with many types of computer system configurations, including, personal computers, desktop computers, laptop computers, message processors, hand-held devices, multi-processor systems, microprocessor-based or programmable consumer electronics, network PCs, minicomputers, mainframe computers, mobile telephones, PDAs, pagers, routers, switches, wearable devices, and the like. The invention may also be practiced in distributed system environments where multiple computer systems (e.g., local and remote systems), which are linked through a network (either by hardwired data links, wireless data links, or by a combination of hardwired and wireless data links), perform tasks. In a distributed system environment, program modules may be located in local and/or remote memory storage devices.

Alternatively, or in addition, at least some of the functionality described herein can be performed, at least in part, by one or more hardware logic components. For example, and without limitation, illustrative types of hardware logic components that can be used include Field-programmable Gate Arrays (FPGAs), Program-specific Integrated Circuits (ASICs), Application-specific Standard Products (ASSPs), System-on-a-chip systems (SOCs), Complex Programmable Logic Devices (CPLDs), central processing units (CPUs), graphics processing units (GPUs), and/or others.

As used herein, the terms “executable module,” “executable component,” “component,” “module,” or “engine” can refer to hardware processing units or to software objects, routines, or methods that may be executed on one or more computer systems. The different components, modules, engines, and services described herein may be implemented as objects or processors that execute on one or more computer systems (e.g., as separate threads).

One will also appreciate how any feature or operation disclosed herein may be combined with any one or combination of the other features and operations disclosed herein. Additionally, the content or feature in any one of the figures may be combined or used in connection with any content or feature used in any of the other figures. In this regard, the content disclosed in any one figure is not mutually exclusive and instead may be combinable with the content from any of the other figures.

The present invention may be embodied in other specific forms without departing from its spirit or characteristics. The described embodiments are to be considered in all respects only as illustrative and not restrictive. The scope of the invention is, therefore, indicated by the appended claims rather than by the foregoing description. All changes which come within the meaning and range of equivalency of the claims are to be embraced within their scope.

What is currently claimed is:

1. A system for facilitating user-interactable design for manufacturability of metal tubing, the system comprising:
one or more processors; and
one or more computer-readable recording media that store instructions that are executable by the one or more processors to configure the system to:
access an input file submitted by a user, the input file comprising a representation of a metal tubing part;
obtain a metal tubing profile based on the metal tubing part;
determine a set of candidate metal tubing materials by comparing the metal tubing profile to a set of available metal tubing materials, wherein the set of available metal tubing materials comprises metal tubing materials that are in stock at one or more manufacturing facilities;
cause presentation of the set of candidate metal tubing materials within a user interface that enables user selection of a particular metal tubing material from the set of candidate metal tubing materials;
in response to detecting one or more differences between profile characteristics of the metal tubing profile and the particular metal tubing material, generate a modified metal tubing part based on the metal tubing part and the profile characteristics of the particular metal tubing material; and
in response to determining that the metal tubing part or the modified metal tubing part is manufacturable in accordance with one or more manufacturing rules, selectively enable order placement functionality within the user interface that triggers manufacturing of the metal tubing part or the modified metal tubing part at the one or more manufacturing facilities.

2. The system of claim 1, wherein the set of candidate metal tubing materials comprises one or more metal tubing materials that comprise profile characteristics that satisfy a threshold similarity to a diameter, a shape, or a wall thickness associated with the metal tubing profile.

3. The system of claim 1, wherein the set of candidate metal tubing materials comprises one or more metal tubing materials that comprise profile characteristics that satisfy a threshold similarity to a diameter associated with the metal tubing profile.

4. The system of claim 1, wherein the set of available metal tubing materials comprises metal tubing materials that are not in stock at the one or more manufacturing facilities.

5. The system of claim 1, wherein the instructions are executable by the one or more processors to configure the system to:
in response to determining that the metal tubing part or the modified metal tubing part is not manufacturable, present an indication of manufacturability of the metal tubing part or the modified metal tubing part that indicates one or more problem regions associated with the metal tubing part or the modified metal tubing part.

6. The system of claim 1, wherein the instructions are executable by the one or more processors to configure the system to cause alternate or simultaneous presentation of the modified metal tubing part and the metal tubing part within the user interface.

7. The system of claim 6, wherein, in response to determining that the metal tubing part or the modified metal tubing part is not manufacturable, the alternate or simultaneous presentation of the modified metal tubing part and the metal tubing part indicates one or more problem regions associated with the metal tubing part or the modified metal tubing part.

8. The system of claim 1, wherein the instructions are executable by the one or more processors to configure the system to, in response to determining that the metal tubing part or the modified metal tubing part is not manufacturable, cause presentation of one or more metal tubing part characteristics within a user interface that enables user selection or modification of the one or more metal tubing part characteristics for the metal tubing part or the modified metal tubing part.

9. The system of claim 8, wherein the one or more metal tubing part characteristics comprise metal tubing material, bevel angle, bevel consistency, metal tube length, cut depth, cut positioning, or cut normalization.

10. The system of claim 8, wherein the instructions are executable by the one or more processors to configure the system to:
generate an updated metal tubing part based on user selection or modification of at least one of the one or more metal tubing part characteristics at the user interface;
determine manufacturability of the updated metal tubing part based by applying one or more manufacturing rules to the updated metal tubing part, wherein the one or more manufacturing rules are based on manufacturing configurations available to one or more manufacturing facilities, wherein the one or more manufacturing rules constrain bevel angle, bevel consistency, metal tubing length, cut clearance, or cut depth; and
in response to determining that the updated metal tubing part is manufacturable in accordance with the one or more manufacturing rules, selectively enable order placement functionality within the user interface that triggers manufacturing of the updated metal tubing part at the one or more manufacturing facilities.

11. A system for facilitating user-interactable design for manufacturability of metal tubing, the system comprising:
one or more processors; and
one or more computer-readable recording media that store instructions that are executable by the one or more processors to configure the system to:
receive an input file submitted by a user, the input file comprising a representation of a metal tubing part;
determine manufacturability of the metal tubing part by applying one or more manufacturing rules to the metal tubing part, wherein the one or more manufacturing rules are based on manufacturing configurations available to one or more manufacturing facilities, wherein the one or more manufacturing rules constrain bevel angle, tooling access, bevel consistency, metal tubing length, cut clearance, or cut depth;
in response to determining that the metal tubing part is not manufacturable in accordance with the one or more manufacturing rules, generate a modified metal tubing part based on the metal tubing part, wherein the modified metal tubing part satisfies the one or more manufacturing rules;
present the modified metal tubing part and the metal tubing part within a user interface, wherein the modified metal tubing part and the metal tubing part are presented simultaneously or alternately; and
selectively enable order placement functionality within the user interface that triggers manufacturing of the modified metal tubing part at the one or more manufacturing facilities.

12. The system of claim 11, wherein, relative to the metal tubing part, the modified metal tubing part comprises a modified bevel angle, a modified bevel consistency, a modified metal tube length, a modified cut depth, a modified cut positioning, modified cut depth, or modified cut normalization.

13. The system of claim 11, wherein the presentation of the modified metal tubing part and the metal tubing part within the user interface indicates one or more problem regions on the metal tubing part.

14. The system of claim 11, wherein the instructions are executable by the one or more processors to configure the system to:
when the metal tubing part is determined to include one or more partial depth cuts, receive user input indicating whether to engrave locations of the one or more partial depth cuts when manufacturing the modified metal tubing part.

15. A system for facilitating user-interactable design for manufacturability of metal tubing, the system comprising:
one or more processors; and
one or more computer-readable recording media that store instructions that are executable by the one or more processors to configure the system to:
receive an input file submitted by a user, the input file comprising a representation of a metal tubing part;
determine manufacturability of the metal tubing part or a modified metal tubing part based on the metal tubing part by applying one or more manufacturing rules to the metal tubing part or the modified metal tubing part, wherein the one or more manufacturing rules are based on manufacturing configurations available to one or more manufacturing facilities, wherein the one or more manufacturing rules constrain bevel angle, tooling access, bevel consistency, metal tubing length, cut clearance, or cut depth;
present an indication of manufacturability of the metal tubing part or the modified metal tubing part within a user interface, wherein, when the metal tubing part or the modified metal tubing part is determined to not be manufacturable, the indication of manufacturability of the metal tubing part or the modified metal tubing part indicates one or more problem regions on the metal tubing part or the modified metal tubing part; and
in response to determining that the metal tubing part or the modified metal tubing part is manufacturable in accordance with the one or more manufacturing rules, selectively enable order placement functionality within the user interface that triggers manufacturing of the metal tubing part or the modified metal tubing part at the one or more manufacturing facilities.

16. The system of claim 15, wherein the modified metal tubing part is generated based on the metal tubing part and one or more profile characteristics of a selected metal tubing material.

17. The system of claim 15, wherein the instructions are executable by the one or more processors to configure the system to cause alternate or simultaneous presentation of the modified metal tubing part and the metal tubing part within the user interface.

18. The system of claim 17, wherein, when the metal tubing part or the modified metal tubing part is determined to not be manufacturable, the alternate or simultaneous presentation of the modified metal tubing part and the metal tubing part indicates the one or more problem regions on the metal tubing part or the modified metal tubing part.

19. The system of claim 15, wherein the instructions are executable by the one or more processors to configure the system to, when the metal tubing part or the modified metal tubing part is not manufacturable, cause presentation of one or more metal tubing part characteristics within a user interface that enables user selection or modification of the one or more metal tubing part characteristics for the metal tubing part or the modified metal tubing part.

20. The system of claim 19, wherein the one or more metal tubing part characteristics comprise metal tubing material, bevel angle, bevel consistency, metal tube length, cut depth, cut positioning, or cut normalization.
